(19) United States
(12) Patent Application Publication
(10) Pub. No.: US 2026/0341356 A1
(43) Pub. Date: Oct. 29, 2026

(54) MEMORY BANK LIGHT SOURCE BASED OPTICAL CONTENT-ADDRESSABLE MEMORY

(71) Applicant: HEWLETT PACKARD ENTERPRISE DEVELOPMENT LP, Spring, TX (US)

(72) Inventors: YANIR LONDON, Spring, TX (US); Stanley Cheung, Milpitas, CA (US); Bassem Tossoun, Santa Barbara, CA (US); Thomas Van Vaerenbergh, Diegem (BE)

(21) Appl. No.: 19/191,499

(22) Filed: Apr. 28, 2025

(51) Int. Cl. G11C 13/04; G02F 3/02; G11C 11/42

(52) U.S. Cl. CPC G11C 13/047; G02F 3/02; G11C 11/42

(57) ABSTRACT

Systems and methods are provided for devices and methods for implementing fully optical content addressable memory (O-CAM). Examples include an input encoder comprising a plurality of light emitting devices configured to store a data word and generate a plurality of optical signals encoded with the data word as a multi-wavelength input signal. Examples also include a comparison engine comprising a plurality of O-CAM cells that have resonant structures configured to store a search word and one or more photodetectors optically coupled to the comparison engine. A respective O-CAM cell is configured to store one of a logic ‘0’, a logic ‘1’, a wildcard value; and a reject value.

### BACKGROUND

Content addressable memory (CAM) is a type of memory that can perform a search operation in which a data string may be input as search content and the resulting output is an address of a location in the memory that stores matching data. This is in contrast to a read operation, in which an address is input and the resulting output is the data stored in the memory location corresponding to the searched address. Certain CAMs may be able to perform both the aforementioned search operation and the aforementioned read operation, while non-CAM memories may be able to perform the read operation but not the search operation.

Ternary CAM (TCAM) is a type of CAM in which the bit cells can store a wildcard data value in addition to two binary data values. When a bit cell that stores the wildcard value is searched, the result is a match regardless of what search criterion is used to search the bit cell. Certain TCAMs may also allow a search to be conducted on the basis of a wildcard search criterion. When a bit cell is searched based on the wildcard search criterion, the result is a match regardless of what value is stored in the bit cell.

### BRIEF DESCRIPTION OF THE DRAWINGS

The present disclosure, in accordance with one or more various examples, is described in detail with reference to the following figures. The figures are provided for purposes of illustration only and merely depict typical, non-limiting aspects of such examples.

FIG. 1 illustrates an example optical search engine in accordance with examples of the present disclosure.

FIG. 2 illustrates an example optical search engine in accordance an example of the present disclosure.

FIGS. 3A-3F illustrate examples results of the optical search engine of FIG. 2.

FIG. 4 illustrates an example optical search engine in accordance another example of the present disclosure.

FIGS. 5A-5F illustrate examples results of the optical search engine of FIG. 4.

FIG. 6 illustrates an example optical search engine in accordance yet another example of the present disclosure.

FIGS. 7A and 7B depict a schematic diagram of an example modulator in accordance with an illustrative implementation of the present disclosure.

FIG. 8 illustrates an example computing device in accordance with examples of the technology disclosed herein.

FIG. 9 is an example computing component that may be used to implement various features of optical comparison engines in accordance with the implementations disclosed herein

FIG. 10 is a computing component that may be used to implement examples of the disclosed technology.

The figures are not exhaustive and do not limit the present disclosure to the precise form disclosed.

### DETAILED DESCRIPTION

Content addressable memory (CAM) is a type of memory generally used in high-speed search applications. CAMs comprise hardware that compares an input pattern against stored binary data. The stored data of a CAM is not accessed by its location, but rather access is performed based on its content. A search word is input to the CAM, the CAM searches for the search word in its contents, and, when found, the CAM returns the address of the location where the found contents reside. CAMs are powerful, efficient, and fast. The input patterns and data in CAMs are represented by logic ‘0’s and logic ‘1’s (generally referred to as a binary CAM or bCAM).

Ternary CAM (TCAM) goes beyond the binary nature of bCAM, allowing for the storage and searching for a third value, referred to as a wildcard or “don't care” bit. In examples disclosed herein, the wildcard symbol may be represented as “X.” A stored wildcard bit is treated like a match, regardless of whether the search criterion for the bit of the stored data word is a logic ‘0’ or a logic ‘1.’ In this way, TCAMs allow for additional complexity as the input pattern can represent a range of patterns rather than only one pattern. For example, an input pattern of “01XX0” could indicate a match for four separate stored words: 01000; 01010; 01100; and 01110. TCAMs perform the in-memory comparison operation in a massively parallel way, enabling extremely high throughput compared to older approaches. This increase in throughput enabled Internet packet routing, real-time network traffic monitoring, and more efficient access control lists, among other improvements in applications requiring fast memory comparisons.

Quaternary CAM (QCAM) goes beyond TCAM, allowing for the storage and searching for a fourth value, referred to as a reject or “always care” symbol. In examples disclosed herein, the reject symbol may be represented as “p.” A stored reject symbol can be treated like a mismatch, regardless of whether the search criterion for the symbol of the stored data word is a logic ‘0’ or a logic ‘1.’ In this way, QCAMs allow for additional complexity as the input pattern can represent a range of patterns rather than only one pattern. As an illustrative example, an input pattern of “01ρρ0” could indicate a mismatch for any pattern that does not contain an “X” as the third and fourth symbol, and the rest of the pattern can return a match.

Increasingly, data transfer is performed using optical communication technologies. Transferring data using optics enables extremely higher bandwidth compared to traditional data transfer electronically. Although applications are frequently using integrated optics to transfer data, existing CAM implementations usually require electronic signals. Accordingly, costly optical to electrical conversions may be required to convert the data from the optical to the electrical domain. Existing CAM implementations can increasingly become bottlenecks due to the need for these conversions, reducing the overall efficiency and throughput possible within a network. Thus, the reduced number of cells used to implement a CAM, such as in the case of a TCAM and QCAM, can provide improved throughput and reduced bottlenecks.

Examples of the technology disclosed herein provide systems and methods for implementing TCAMs and/or QCAMs in the optical domain with full ternary and quaternary search capabilities, respectively. In various examples, an optical CAM (O-CAM) may include an input encoder optically coupled to a comparison engine. The input encoder may be configured to emit a multi-wavelength input signal representative of one or more data words. For example, the input encoder may include a plurality of light emitting devices configured to store a data word and generate a plurality of optical signals encoded with the data word as the multi-wavelength input signal. The comparison engine may comprise a plurality of O-CAM cells, which may be configured to store a search word. For example, the O-CAM cells may comprise resonant structures configured to store the search word. Examples herein may also include one or more photodetectors optically coupled to the comparison engine, for example, to the plurality of O-CAM cells of the comparison engine. In examples, the comparison engine can be configured to couple light of the multi-wavelength input signal(s) into the photodetector(s) to indicate a mismatch between a symbol of the search word and a symbol of the data word.

The examples disclosed herein provide compact and scalable O-CAM implementations. By leveraging an input encoder that can emit light to represent encoded data word signals and a comparison engine capable of storing a search word, the examples herein may require half the number of cells compared to prior O-CAM approaches. For example, by using light emitting devices integrated into cells of the input encoder, each cell can be tuned to store a symbol of a data word and encode the stored symbol onto optical signals. Likewise, each cell of the comparison engine can be tuned to store a symbol of a search word using a single resonant structure. Whereas, prior approaches generally require two or more resonant structures to represent a single symbol, which necessitates a larger physical footprint and increases complexity in controlling and synchronization.

In some illustrative examples, the input encoder may comprise a plurality of encoding cells, which may include tunable optical sources. In examples, each encoding cell may comprise an optical resonant structure, such as an optical modulator, having a light emitting device integrated therein. In examples, the optical resonant structure may be microrings (MRRs), but other optical resonant structures may be utilized as desired. The light emitting device can be driven, for example, by a programming controller, to emit light. In examples, a tuning component may be included that can be driven, for example, by a programming controller, to provide for tuning of the wavelength of light emitted by the light emitting device. The emission of light and the wavelengths thereof can be driven according to an O-CAM encoding scheme. In examples, the tuning may be non-volatile, which can provide for non-volatile storage of the O-CAM data word. Thus, through tuning of each encoding cell, a plurality of optical signals can be generated and supplied to an input routing element, which provides the encoded data word optical signals to the comparison engine as a multi-wavelength input signal.

As alluded to above, the comparison engine may comprise the plurality of O-CAM cells that can be configured to store a search word. In examples, each O-CAM cell may comprise an optical resonant structure, such as an optical modulator. In examples, the optical resonant structure may be MRRs, but other optical resonant structures may be utilized as desired. The O-CAM cells can comprise tuning components, which can be driven, for example, by a programming controller, to tune a resonance frequency of the resonant structure. The tuning of the resonance structures can be driven according to an O-CAM encoding scheme. By tuning the resonance wavelength at each O-CAM cell, the O-CAM cells can store a search word and compare the stored search word against the encoded data word optical signals. For example, the multi-wavelength input signal can be supplied to the comparison engine via the input routing element. Based on the tuning of the resonance wavelengths of the O-CAM cells, light will either couple into respective resonant structures or pass the respective resonant structure.

The comparison engine can be optically coupled to the one or more photodetectors, which can be configured to detect the presence of light (e.g., an intensity of light equal to or greater than a threshold amplitude) or the absence of light (e.g., an intensity of light below the threshold amplitude). Based on the detection of light, the one or more photodetectors may be configured to generate an electrical response (e.g., a current) that indicates a match between the search word stored at the comparison engine and the encoded data word signals or a mismatch therebetween. For example, a mismatch may be indicated based on (e.g., responsive to) detecting the presence of light above the threshold amplitude.

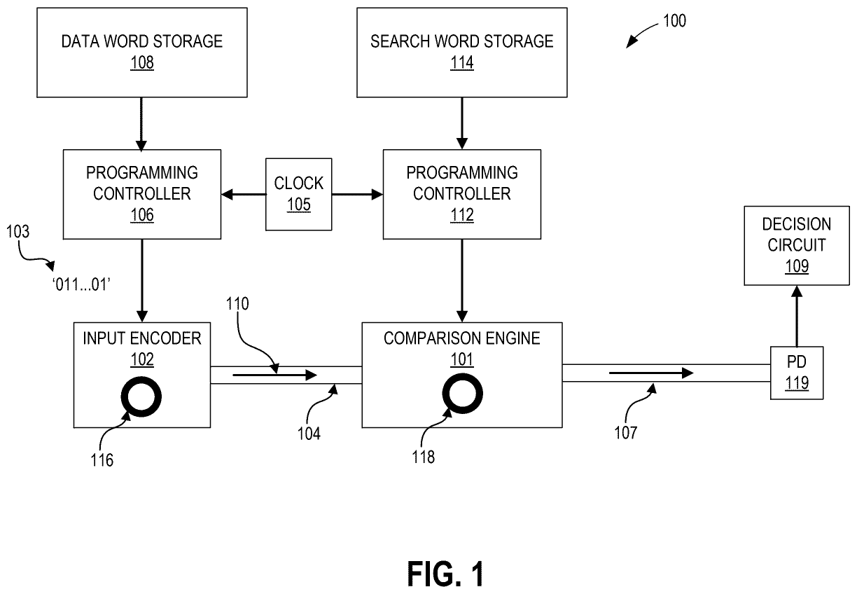

FIG. 1 illustrates an example optical search engine 100 in accordance with examples of the present disclosure. The optical search engine 100 is provided for illustrative purposes only and should not be interpreted as limiting the scope of the disclosed technology to only the depicted example. For ease of discussion, the optical search engine 100 of FIG. 1 is discussed with respect to comparison of a data word and a search word through the use of an input encoder 102 and a comparison engine 101. However, in various examples, the optical search engine 100 can include a plurality of input encoders 102 associated with a plurality of data words to enable comparison of a plurality of data words against a search word. Furthermore, the optical search engine 100 may include a plurality of comparison engines 101 associated with a plurality of search words to enable comparison of a plurality of data words and a plurality of searched words.

As shown in FIG. 1, a data word 103 can be received by an input encoder 102 configured to store and encode one or more data words 103, as well as transmit an encoded data word signal 110 (also referred to herein as an encoded data word input signal or data word input signal). In some examples, the optical search engine 100 may include one or more input encoders 102, each input encoder 102 can be configured to store a data word 103 of one or more received data words 103. In some examples, the input encoder 102 can provide for non-volatile storage of symbols of one or more received data words 103. The one or more input encoders 102 can also encode a data word 103 of one or more received data words 103 according to an encoding scheme. In some examples, a data word engine input (not shown in FIG. 1) may be configured to receive the one or more data words 103 and transmit each received one or more data words to the input encoder 102, which can be operated to store the one or more data words 103. The one or more data words 103 may be received over an electrical connection (e.g., over an electrical trace), over an optical routing element (e.g., a waveguide, optical fiber), or a combination of both.

In various examples, the input encoder 102 may be configured to encode the one or more received data words 103 in the wavelength domain (e.g., wavelength division multiplexing (WDM)) and/or spatial domain (e.g., multiplexing over a spatial dimension). In examples, symbols of a given data word 103 may be encoded using a plurality different wavelengths of light according to the encoding scheme. In some examples, each data word 103 may be encoded in the time domain (e.g., using different time slots). For example, the symbols of a first data word may be encoded in the wavelength domain during a first time slot using different wavelengths to encode each symbol, while symbols of another data word may be encoded during a second time slot using the different wavelengths. In another example, each data word 103 may be encoded in the spatial domain (e.g., a plurality of input encoders 102 distributed in spatial domain). For example, the symbols of a first data word may be encoded by a first input encoder using different wavelengths, while symbols of another data word may be encoded by a second input encoder using the different wavelengths.

In various examples, the input encoder 102 may comprise one or more resonant structures 116 capable of being driven by an electronic signal to tune optical characteristics of the one or more resonant structures 116. The symbols of a given data word 103 may be stored and encoded onto optical signals by driving the one or more resonant structures 116 to tune the optical characteristics to represent the symbols of the data word 103 based on the encoding scheme. In some examples, the one or more resonant structures 116 may be connected in series with the output of the first resonant structure optically coupled to the input of a second resonant structure, the output of the second resonant structure optically coupled to a third resonant structure, and so on. For example, the resonant structures 116 may be implemented as, but not limited to waveguide resonators (e.g., microring modulators), multipath interferometers (e.g. MZI), photonic crystals (e.g., LiNbO₃), phase shifters, polarization filters, lattice filters, or other resonating components.

In various examples, the one or more resonant structure 116 can include one or more light emitting devices. In examples, the light emitting devices can be configured to generate and emit light. For example, a respective resonant structure 116 may include a light emitting device formed as an optically active medium integrated into the structures of the respective resonant structure 116. The optically active medium can be driven (e.g., by programming controller 106) to cause light emission. By driving the light emitting device, the respective resonant structure 116 can be switched from an off state (e.g., no light) to an on state (e.g., emitting light) and vice versa.

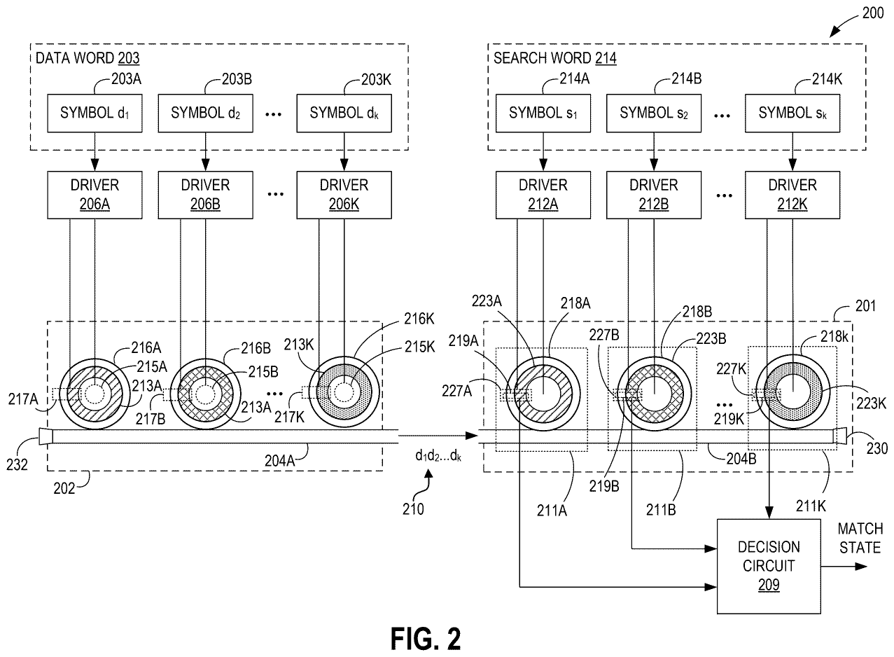

In various examples, the one or more resonant structures 116 can be communicatively coupled to one or more tuning components (shown in FIGS. 2, 4, and 6). The one or more tuning components may be capable of changing an optical characteristic of the one or more resonant structures 116 to enable tuning of the performance of respective resonant structures 116. In various examples, the one or more tuning components can comprise one or more devices configured to change a refractive index of a core or cladding of the one or more resonant structures 116, control the number of free carriers, and/or create a red and/or blue shift of a resonance wavelength of the one or more resonant structures 116. Tuning of a respective resonant structure 116 may enable the respective resonant structure 116 to induce a wavelength shift in the light emitted by the resonant structure 116. For example, while in the on state, the tuning component may be driven (e.g., by the programming controller 106) to change the resonant structure 116 between a first on state during which light can be emitted at a first wavelength (λ₀) and a second on state in which light can be emitted in a second wavelength (λ₁). By tuning in this way, the resonant structure 116 can be able to store, as well, encode, symbols of a data word 103 onto optical signals. Non-limiting examples of tuning components include heaters, electrical contacts, and capacitive structures, among other devices used to tune the resonance wavelength of optical components.

In various examples, a programming controller 106 (also referred to as a driver) can be used to drive the one or more resonant structures 116 to store and represent the symbol positions of the one or more data words. In various examples, the programming controller 106 can be configured to control tuning of all of the resonant structures 116. In other examples a plurality of programming controllers 106 can be included that are configured to tune one or more resonant structures 116. In some examples, the program controller 106 can be operated to drive light emitting devices of the one or more resonant structures 116 to switch between the on and off states. In some examples, the program controller 106 can also be operated to drive the tuning components so to change the optical characteristic of the one or more resonant structures 116 to represent the first on state and second on state. In various examples, the programming controller 106 can comprise a processing component, a field programmable gate array (FPGA), an application specific integrated circuit (ASIC), or other type of processor present in computing systems. In some examples, the programming controller 106 can comprise a central processing unit (CPU), a graphics processing unit (GPU), or other processing component external to the optical search engine 100.

Each of the data words 103 can be maintained in a data word storage 108 in various examples. The data word storage 108 can comprise a non-transitory machine-readable storage medium configured to store one or more words. Non-limiting examples of the data word storage 108 can comprise common forms of memory including RAM, PROM, EPROM, FLASH-EPROM, NVRAM, memristors, optical storage memories, among electrical, optical, or electro-optical storage medium. In various examples, the data word storage 108 can comprise one or more types of volatile and/or non-volatile memory. In various examples, the data word storage 108 may be a dedicated memory component for the optical search engine 100 configured to store stored words, while in other examples the data word storage 108 can be a partition or other assigned space in a shared memory component. The data word storage 108 may be implemented in a storage area network (SAN) or other networked storage solution. The programming controller 106 can be communicatively coupled to the data word storage 108 and configured to retrieve a stored word for encoding onto optical signals by the input encoder 102. The programming controller 106 can maintain a mapping of stored words to the resonant structures of the input encoder in a dedicated memory component of the programming controller 106 (not shown in FIG. 1), in the data word storage 108, or in another separate memory component communicatively coupled to the optical search engine 100 (not shown in FIG. 1), or a combination thereof. In some examples, each stored word can be stored in the data word storage 108 in its encoded state, while in other examples the stored words can be stored in an un-encoded state. The method of storage (encoded or un-encoded) depends on the requirements of the application in which the O-CAM is implemented.

In various examples, an encoded data word signal 110 can comprise k encoded data word symbol values, where k is the number of symbol positions in the stored data word D. As a non-limiting example, the data word 103 may comprise 8 symbol positions, and the encoded data word signal 110 can comprise 8 encoded data word symbol values representing the 8 symbol positions. As a non-limiting example, a first encoded data word D₁ may comprise k encoded stored data words symbol values d₁₋₁, . . . dₖ₋₁ and the second encoded data word D₂ may comprise k encoded stored data word signal symbol values d₁₋₂, . . . dₖ₋₂. In various examples, the encoded data word signal symbol values associated with a stored data word may be non-continuous (i.e., the encoded stored data word signal symbol values may be separated by one or more encoded search signal symbol values not associated with the symbol position). A key can be included to descramble the light signals at the photodetector 119.

The encoded data word signal 110 generated by the input encoder 102 can be coupled to an input routing element 104. The input routing element 104 may comprise an optical waveguide, an optical fiber, or other optical routing medium known in the art. The input routing element 104 may be made of, but not limited to, one or more of gallium arsenide (GaAs), indium phosphide (InP), silicon (Si), silicon nitride (SiN), LiNbO₃, glass, and silica, among other materials. In various examples, the input routing element 104 may be disposed in a silicon photonics assembly. One or more of the elements illustrated in FIG. 1 may be disposed in a silicon photonics assembly. The input routing element 104 can include one or more coupling components (not shown in FIG. 1) disposed at the first end to couple the encoded data word signal 110 from the input encoder 102 and at the second end to couple the encoded data word signal 110 into the comparison engine 101. In various examples, a plurality of input routing elements 104 may be included and each input routing element 104 can be configured to couple one of a plurality of encoded data word signals 110 from a plurality of input encoders 102 to a comparison engine 101.

To perform a search operation, the comparison engine 101 can be driven to store a search word, in some examples. The comparison engine 101, in some examples, can include one or more resonant structures 118 that can be modulated to store one or more search word symbols. In examples, the resonant structures 118 can be driven to provide for non-volatile storage of the search word symbols. In some examples, the one or more resonant structures 118 may be connected in series with the output of the first resonant structure optically coupled to the input of a second resonant structure, the output of the second resonant structure optically coupled to a third resonant structure, and so on. In various examples, the resonant structures of comparison engine 101 may include, but not limited to waveguide resonators (e.g., microring modulators), multipath interferometers (e.g. Mach Zehnder interferometer (MZI)), photonic crystals (e.g., lithium niobate (LiNbO₃)), phase shifters, polarization filters, lattice filters, or other resonating components capable of being driven by an electronic signal to tune the optical characteristics of the comparison engine 101.

In various examples, the optical search engine 100 can include a plurality of comparison engines 101. In some examples, each comparison engine 101 can be configured to compare a different search word against the encoded data word signal 110. In some examples, the comparison engines 101 may be configured in parallel. In one example, a copy of the encoded data word signal 110 can be optically coupled to an input of each of the one or more comparison engines 101, each encoded with a different search word. In another example, a plurality of encoded data word signal 110 can be optically coupled to one or more inputs of the one or more comparison engines 101 to compare a plurality of stored data words and a plurality of search words. For example, the optical search engine 100 can include a plurality of input encoders 102 configured to generate a plurality of encoded data word signals 110 by encoding a plurality of data words 103. The plurality of encoded data word signals 110 can be optically coupled to one or more inputs of the one or more comparison engines 101.

In various examples, a programming controller 112 (also referred to as a driver) can be used to tune the one or more comparison engines 101 to store and represent the symbol positions of the one or more search words. In various examples, the programming controller 112 can be configured to control tuning of the one or more resonant structures 118. In some examples, the programming controller 112 may be configured to control tuning of all resonant structures 118. In other examples, a plurality of programming controllers 112 can be included, each of which may be configured to tune one or more of the resonant structures 118. Each comparison engine 101 can be communicatively coupled to one or more tuning components, each of the one or more tuning components may be capable of changing an optical characteristic of the one or more resonant structures 118 to enable tuning of the performance of the comparison engine 101. In various examples, the one or more tuning components can comprise one or more devices configured to change the refractive index of the core or cladding of the one or more resonant structures, control the number of free carriers, and/or create a red and/or blue shift of the resonance wavelength of the one or more resonant structures. Non-limiting examples of tuning components include heaters, electrical contacts, among other devices used to tune the resonance wavelength of optical components. In various examples, the programming controller 112 can comprise a processing component, a field programmable gate array (FPGA), an application specific integrated circuit (ASIC), or other type of processor present in computing systems. In some examples, the programming controller 106 can comprise a central processing unit (CPU), a graphics processing unit (GPU), or other processing component external to the optical search engine 100. In some examples the programming controllers 112 and 106 may be the same or different programming controllers.

Each of the search words can be maintained in a search word storage 114 in various examples. The search word storage 114 can comprise a non-transitory machine-readable storage medium configured to store one or more words. Non-limiting examples of the search word storage 114 can comprise common forms of memory including RAM, PROM, EPROM, FLASH-EPROM, NVRAM, memristors, optical storage memories, among electrical, optical, or electro-optical storage medium. In various examples, the search word storage 114 can comprise one or more types of volatile and/or non-volatile memory. In various examples, the search word storage 114 may be a dedicated memory component for the optical search engine 100 configured to store stored words, while in other examples the search word storage 114 can be a partition or other assigned space in a shared memory component. The search word storage 114 may be implemented in a storage area network (SAN) or other networked storage solution. In some examples, the search word storage 114 and the data word storage 108 may be the same data store or different data stores. The programming controller 112 can be communicatively coupled to the search word storage 114 and configured to retrieve a stored search word to compare against the encoded data word through the comparison engine 101. The programming controller 116 can maintain a mapping of search words to resonant structures of the comparison engine 101 in a dedicated memory component of the programming controller 112, in the search word storage 114, or in another separate memory component communicatively coupled to the optical search engine 100 (not shown in FIG. 1), or a combination thereof. In some examples, each search word can be stored in the search word storage 114 in its encoded state, while in other examples the stored words can be stored in an un-encoded state. The method of storage (encoded or un-encoded) depends on the requirements of the application in which the O-CAM is implemented.

In various examples, the encoding of the input data word 103 can be performed in accordance with a clock (CLK) signal from clock 105. The CLK signal can be used by the programming controller 106 to identify each of the encoded data word symbol values dᵢ associated with each respective symbol position of the data word 103. The programming controller 106 can generate a drive signal used to configure the input encoder to represent the input data word 103. In various examples, the CLK signal from clock 105 can also be used by the programming controller 112 to generate the drive signal used to configure the comparison engine 101 to represent the search word. In some examples, the programming controllers 106 and/or 112 can include one or more circuits to delay the CLK signal from clock 105 such that the respective programming controller applies drive signals in synchronously between the input encoder 102 and the comparison engine 101.

As seen in FIG. 1, one or more photodetectors 119 can be coupled to an output routing element 107 in various examples. The one or more photodetectors 119 can be configured to detect the presence (or absence of light) output by the comparison engine 101, thereby detecting the mismatch and/or match for a respective symbol position. For example, the one or more photodetectors 119 may output a current response indicative of light detected by the one or more photodetectors 119 (e.g., light equal to or above a threshold amplitude A), thereby indicating a mismatch. Whereas, based on (e.g., in response to) detecting a match (e.g., light below the threshold amplitude A), the one or more photodetectors 119 may not output a current (or output a current at or below a background noise level). The one or more photodetectors 119 can include circuitry configured to output the current response representative of a detected match/mismatch.

In various examples, the output routing element 107 may be a waveguide that is optically coupled to the comparison engine 101. For example, the output routing element 107 may comprise a one or more output routing elements 107, each of which is optically coupled (e.g., evanescently coupled) to respective resonant structures 118. In this case, the one or more output routing elements 107 may be configured as drop waveguides that drop light propagating on the one or more resonant structures 118 to one or more photodetectors 119. In another example, the output routing element 107 may be a single waveguide optically coupled to each of the one or more resonant structures 118 and configured to supply an aggregate optical signal to a single photodetector 119. In these examples, the one or more photodetectors 119 can comprise photodiodes or other type of circuit-type detector of photons.

In another example, the one or more photodetectors 119 may be integrated into the structures of the one or more resonant structures 118 (not shown in FIG. 1). In this case, the output routing element 107 may be light-conducting mediums of the one or more resonant structures 118. For example, the one or more photodetectors 119 may be incorporated into sections of the one or more resonant structures 118. The resonant structure 118 may include an absorbing structure within or adjacent to light-conducting medium that can be used to detect light intensity therein. In this case, the in-situ absorbing structure may generate an electrical signal indicative of the light intensity detected by the in-situ absorbing structure. Illustrative examples of absorbing structures integrated into a microring are described, for example, in U.S. Pat. Nos. 11,442,235 and 11,927,819, each assigned to the Applicant and the disclosures of which are incorporated herein by reference.

The one or more photodetectors 119 can be electrically connected to a decision circuit 109 that receives the electrical response representative of the intensity of light detected by the one or more photodetectors 119. The decision circuit 109 may detect the current from the one or more photodetectors 119 and output a memory address corresponding to the data word represented by the encoded data word signal 110. In some examples, the decision circuit 109 may include an encoder circuit configured to generate the memory address corresponding to the data word for which a match indication is detected by a photodetector 119. In some examples, each decision circuit 109 may send the indication to a (or comprise a) processing circuit configured to identify the memory address associated with the specific data word represented by the encoded data word signal 110 and output an electrical signal to a memory controller or other device controller access to the memory storage.

In various examples, the decision circuit 109 can be configured to integrate the mismatches during a search cycle of the data word 103, enabling the decision circuit 109 to determine the sum of all mismatches between the data word 103 and the search word represented by the comparison engine 101. In various examples, the photodetectors 119 can include circuitry configured to perform the integration of light for the duration of the search cycle, while in some examples the photodetectors 119 can be configured with a long time-constant (TC) to enable integration to occur within the photodetector. In some examples, the decision circuit 109 can be configured to flag or otherwise identify at which symbol positions a mismatch occurred.

FIG. 2 is an example optical search engine 200 in accordance an example of the present disclosure. The optical search engine 200, in this example, may be implemented to perform WDM O-CAM in accordance with the examples herein. The optical search engine 200 is provided for illustrative purposes only and should not be interpreted as limiting the scope of the disclosed technology to only the depicted example. In examples, optical search engine 200 may be implemented to compare a data word 203 represented as symbols 203A-203K and a search word 214 represented as symbols 214A-214K through the use of an input encoder 202 and a comparison engine 201. In various examples, optical search engine 200 performs the comparison optically using data words and search words that can be stored in a memory, such as data word storage 108 and search word storage 114 of FIG. 1, respectively.

In the example of FIG. 2, the input encoder 202 can be optically coupled to the comparison engine 201 through input routing elements 204A and 204B. For example, the comparison engine 201 may be optically coupled to a first end of input routing elements 204A, having a terminator 232 on an opposite end configured to mitigate back reflections. The input encoder 202 may be an example implementation of the input encoder 102 and the comparison engine 201 may be an example implementation of the comparison engine 101. Likewise, the input routing elements 204A and 204B may be examples implementations of input routing element 104. Input routing elements 204A and 204B may be separate elements that are optically coupled via one or more intermediate optical components (not shown), such as optical couplers or other routing elements. In another example, input routing elements 204A and 204B may represent different portions of the same routing element, for example, input routing element 204A may represent an input port of a routing element coupled to the input encoder 202 and the input routing element 204B may represent an output port of the routing element coupled to the comparison engine 201.

In the example of FIG. 2, the input encoder 202 comprises a plurality of encoding cells, represented as a plurality of resonant structures 216A-216K (e.g., example implementations of one or more resonant structures 116). As used herein, a “cell” may refer to structure that can be implemented to store a symbol value, such as logic ‘0’, logic ‘1’, ‘X’ (a wildcard value or “don't care” symbol), or ‘ρ’ (a reject value or “always care” symbol). Thus, for example, an encoding cell may refer to a structure that can be implemented to store a symbol value of a data word, which can be encoded into optical signals.

The plurality of resonant structures 216A-216K may be capable of being driven by one or more electronic signals to tune optical characteristics of the one or more resonant structures 216A-216K (collectively referred to herein as resonant structures 216 or singularly as resonant structure 216). The symbols 203A-203K of the data word 203 may be encoded onto optical signals by driving the plurality of resonant structures 216 to tune the optical characteristics to represent the symbols 203A-203K. The resonant structures 216, in this example, are connected in series with the output of a resonant structure 216A optically coupled to the input of resonant structure 216B, the output of the resonant structure 216B optically coupled to a next resonant structure, and so on. In an illustrative example, each resonant structure 216 is implemented as a waveguide resonator (e.g., MRR, ring filter, or the like) or other resonating component capable of being driven by an electronic signal to tune the performance characteristics of the resonant structures 216. In the particular example of FIG. 2, the resonant structures 216 are provided as microring resonators (MRRs).

In the example of FIG. 2, each resonant structure 216 can be driven to resonate at one or more resonance wavelengths of a distinct set of resonance wavelengths (e.g., each resonant structure 216 corresponds to a particular set of resonance wavelengths). In examples, each resonant structure 216 can be driven to resonate at a desired first resonance wavelength (λ_{i,0}) (e.g., a first on state), where i is an integer between 1 and k representing a respective resonant structure 216. For example, resonant structure 216A may be driven to resonate at a wavelength (λ_{1,0}), resonant structure 216B may be driven to resonate at a wavelength (λ_{2,0}), . . . , and resonant structure 216K may be driven to resonate at a wavelength (λ_{k,0}). The resonance wavelength of each resonant structure 216 may also be tuned to a second resonance wavelength (λ_{i,1}) (e.g., a second on state). For example, resonant structure 216A may be driven to resonate at a wavelength (λ_{1,1}), resonant structure 216B may be driven to resonate at a wavelength (λ_{2,1}), . . . , and resonant structure 216K may be driven to resonate at a wavelength (λ_{k,1})). Thus, each resonant structure 216 may be capable of resonating at a distinct set of wavelengths (e.g., a first resonance wavelength (λ_{i,0}) and a second resonance wavelength (λ_{i,1})). In some examples, a resonant structure 216 may resonate at one resonance wavelength, while in other examples a resonant structure 216 may resonate at multiple resonance wavelengths simultaneously (e.g., through multimodal waveguide properties).

In examples, resonant structures 216 comprise light-conducting mediums 213A-213K, light emitting devices 215A-215K, and tuning components 217A-217K. In examples, resonant structures 216 may be driven to generate and emit light, which can be tuned to one or more resonance wavelengths to represent symbols 203A-203K. In this case, the input encoder 202 may be implemented as a memory bank laser (MBL) circuit, which stores data word 203 through tuning of the tuning components 217A-217K. In the particular example of FIG. 2, the MBL comprises a plurality of MRR lasers as the resonant structures 216. Each resonant structure 216 may be driven so to output an optical signal representing one of symbols 203A-203K. The following description of the resonant structures 216 will be provided with respect to resonant structure 216A as an illustrative example.

The light-conducting medium 213A may comprise an optical waveguide such as a semiconductor waveguide. In examples, the light emitting device 215A may be integrated into the structures of the light-conducting medium 213A. The light emitting device 215A can be configured for generation and emission of light, which can be injected or otherwise coupled into the light-conducting medium 213A. For example, the light emitting device 215A may comprise an optically active medium formed in the structures of the light-conducting medium 213A. Application of a voltage bias (e.g., a seed voltage bias) across the optically active medium may cause an accumulation of free charge carriers that may lead to stimulated emission within the optically active medium. This stimulated emission may function as a seed signal that stimulates further emissions causing the generation of light. The generated light may be injected (e.g., emitted) into the light-conducting medium 213A. The light may then resonate within the light-conducting medium 213A and couple from the resonant structure 216A into the input routing element 204A. Adjusting of the voltage bias (e.g., via driver 206A) to cause light emission may be an example of turning the resonant structure 216A on and off (e.g., transiting between the on state and off state).

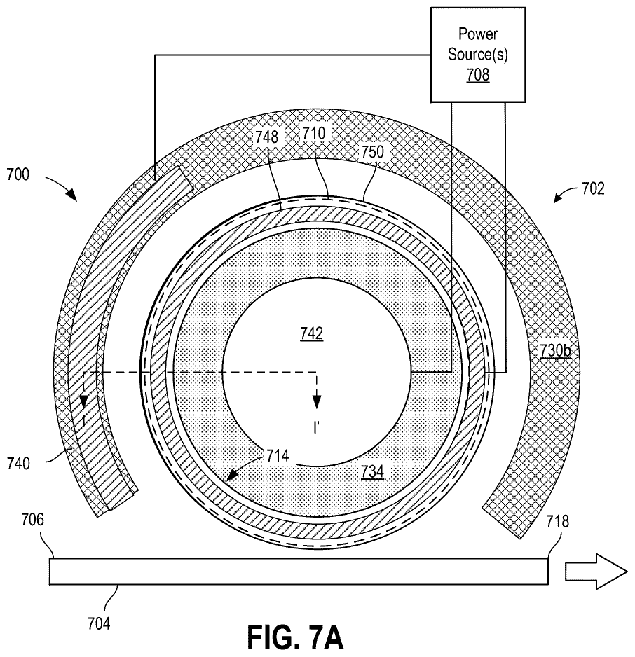

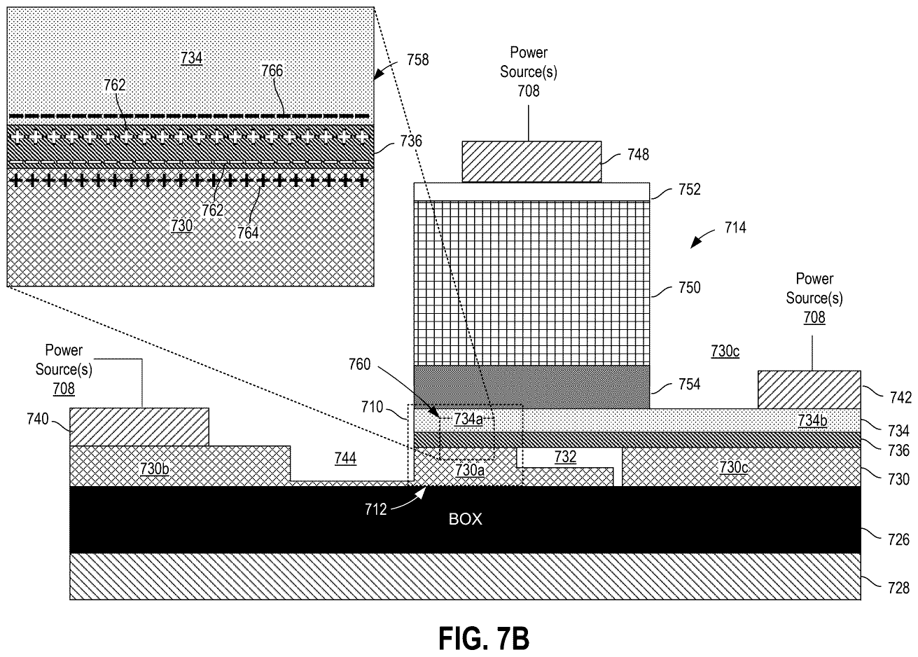

In various examples, the resonant structure 216A can be communicatively coupled to one or more tuning components 217A. The tuning component 217A may be capable of changing an optical characteristic of the resonant structures 216A to enable tuning of the performance of the resonant structure 216. In various examples, the tuning component 217A can comprise one or more devices configured to change a refractive index of the light-conducting medium 213A, control the number of free carriers, and/or create a red and/or blue shift of a resonance wavelength of the resonant structure 216A. Tuning the resonant structure 216A may induce a wavelength shift in the light emitted by the resonant structure 216A. For example, while driven in the on state, the tuning component 217A may be driven to change the resonant structure 216A between a first on state during which light can be emitted at the first resonance wavelength (λ_{i,0}) and a second on state in which light can be emitted in a second resonance wavelength (λ_{i,1}). tuning component 217A may be include, but is not limited to, heaters, electrical contacts, and capacitive structures, among other devices used to tune the resonance wavelength of optical components. In some examples, this tuning may be a non-volatile tuning, as described below in connection with FIGS. 7A-7B, which can provide for non-volatile storage of the data word 203.

In examples, drivers 206A-206K (e.g., an example implementation of programming controller 106 of FIG. 1) can be used to drive the resonant structures 216 to represent the symbol positions of the data word 203. In the example of FIG. 2, each of the drivers 206A-206K can be configured to control tuning of a corresponding resonant structure 216. However, in other examples, drivers 206A-206K may be implemented as a single driver configured to control the tuning of the plurality of resonant structures 216. In some examples, the drivers 206A-206K can be operated to drive the light emitting devices 215A-215K to switch respective resonant structures 216 between the on and off states. In some examples, the drivers 206A-206K can also be operated to drive the tuning components 217A-217K so to change the optical characteristic of the respective resonant structures 216 to tune between the first on state and second on state.

The drivers 206A-206K can be communicatively coupled to the memory storing the data word (e.g., data word storage 108) and configured to retrieve a stored data word for storage and encoding onto optical signals by the input encoder 202. The drivers 206A-206K can maintain a mapping of symbols 203A-203K to the resonant structures 216 in a dedicated memory component, in the data word storage, or in another separate memory component communicatively coupled to the drivers 206A-206K, or a combination thereof.

Table 1 illustrates an example encoding scheme in accordance with a TCAM implementation of the technology disclosed herein.

TABLE 1

| Data Word | Encode Stored Data |
|---|---|
| Symbol Value (dᵢ) | Word Symbol State |
| 0 | λ_{i, 0} |
| 1 | λ_{i, 1} |
| X | Off |

As shown in Table 1, data word 203 can be represented by the plurality of encoded data word symbol values d₁, d₂, . . . dₖ (e.g., symbols 203A-203K in FIG. 2). To provide a data word symbol value dᵢ (where i is an integer between 1 and k) of logic ‘0’, light having an amplitude A can be transmitted at the first resonance wavelength (λ_{i,0}) within the data word symbol value dᵢ associated with the symbol position. As an example, resonant structure 216A can be driven to represent a logic ‘0’ for data word symbol value dᵢ (e.g. symbol 203A) by turning on the light emitting device 215A and tuning the resonant structure 216A to the first on state so to emit light at its first resonance wavelength (λ_{1,0}) via tuning component 217A. In this example, i can represent the symbol position from 1 to k, as well as the corresponding resonant structure 216 to be driven to output an optical signal representing the corresponding symbol position. For the stored data symbol value dᵢ of logic ‘1’, light having an amplitude of A at the second resonance wavelength (λ_{i,1}) can be transmitted within the data word symbol value dᵢ associated with the symbol position. As an example, the resonant structure 216A can be driven to represent a logic ‘1’ by turning on the light emitting device 215A and tuning the resonant structure to the second on state so to emit light at its second resonance wavelength (λ_{1,1}) via tuning component 217A. To provide a stored data word symbol value dᵢ of wildcard symbol ‘X’, light amplitude of 0 can be transmitted in the data word symbol value dᵢ associated with the symbol position. For example, the resonant structure 216A can be driven to represent a wildcard symbol ‘X’ by turning off the light emitting device 215A coupled thereto. The other resonant structures 216 may be similarly driven to represent a corresponding symbol position.

Accordingly, input encoder 202 may be configured to encode the data word 203 in the wavelength domain. Said another way, each symbol 203A-203K of the data word 203 may be encoded using a different set of resonance wavelengths (sometimes referred to herein as encoding wavelengths), corresponding to a respective resonant structure 216, according to the encoding scheme described in Table 1. For example, the first symbol 203A can be encoded using a first set of resonance wavelengths corresponding to resonant structure 216A (e.g., λ_{1,0} and λ_{1,1}), the second symbol 203B can be encoded using a second set of wavelengths corresponding to resonant structure 216B (e.g., λ_{2,0} and λ_{2,1}), and so on until a kth symbol 203K, which can be encoded a kth set of wavelengths corresponding to resonant structure 216K (e.g., λ_{k,0} and λ_{k,1}).

In examples, a threshold amplitude A can be used to distinguish between light having an amplitude of 0 and light having an amplitude A. For example, light having an amplitude of 0 may refer to light having an amplitude that is less than the threshold amplitude A and, therefore, can be considered as no light transmitted. In this case, the threshold amplitude A may be selected so to distinguish between light representing a logic ‘0’ and light representing logic ‘1’, as well as to distinguish between light representing a logic ‘0’ or ‘1’ and background noise occurring when representing the wildcard symbol “X”. Whereas, light having an amplitude of A may refer to light having an amplitude of at least A (e.g., equal to or above the threshold amplitude A). Thus, as an example, to provide a logic symbol ‘0’ or ‘1’, light having an amplitude of equal to or above the threshold amplitude A at a respective wavelength can be transmitted, while a wildcard symbol ‘X’ can be provided by light having an amplitude of less than the threshold amplitude A.

In some examples, the amplitude A may be the same value for each symbol position, while in other examples at least one symbol position may transmit light of a different amplitude A than at least one other symbol position. In various examples, the amplitude A for each symbol can decrease from a maximum amplitude A₀ for the first encoded search symbol value d₁ to a minimum amplitude Aₙ for the kth encoded stored data word symbol value dₖ.

As shown in FIG. 2, data word 203 can be received by the input encoder 202 as a plurality of symbols 203A-203K, each corresponding to an encoded data word symbol values d₁, d₂, . . . dₖ. The data word symbols 203A-203K can be encoded by driving a plurality of resonant structures 216A-216K as described above to generate and output an encoded data word signal 210, similar to the encoding encoded data word signal 110 discussed with respect to FIG. 1.

An encoded data word signal 210 can comprise k optical signals, each of which is encoded with data word symbol values according to encoding scheme of Table 1, where k is the number of symbol positions in the stored data word D. As a non-limiting example, the data word 203 may comprise 8 symbol positions, and the encoded data word signal 110 can comprise 8 optical signals encoded with data word symbol values representing the 8 symbol positions.

In examples, different data words may be encoded during different time slots. As a non-limiting example, a first encoded data word D₁ may comprise k encoded stored data words symbol values d₁₋₁, . . . dₖ₋₁ and the second encoded data word D₂ may comprise k encoded stored data word signal symbol values d₁₋₂, . . . dₖ₋₂. The second encoded data word D₂ may be transmitted during a subsequent time slot.

The encoded data word signal 210 generated by the input encoder 202 can be coupled to an input routing element 204A. In examples in which the input routing elements 204A and 204B are separate routing elements, the input routing element 204A can include one or more coupling components to couple the encoded data word signal 210 from the input encoder 204A and into the input routing element 204B to couple the encoded search signal 210 into the comparison engine 201. In examples in which the input routing elements 204A and 204B represent different portions of the same routing element, the encoded data word signal 210 is coupled into the input routing element 204A, while the input routing element 204B couples the encoded data word signal 210 into the comparison engine 201 as a multi-wavelength input signal (e.g., an input signal comprising one or more optical signals, each at a distinct wavelength)

To perform a search operation, the comparison engine 201 can be driven to store search word 214, in some examples. In the example of FIG. 2, the comparison engine 201 includes one or more O-CAM cells 211A-211K. The O-CAM cells 211A-211K may comprise resonant structures 218A-218K that can be driven to store search word symbols 214A-214K. The resonant structures 218A-218K (collectively referred to herein as resonant structures 218 or singularly as resonant structure 218) may be driven by one or more electronic signals to tune optical characteristics of the resonant structures 218. The symbols 214A-214K of search word 214 may be stored in each O-CAM cell by driving the plurality of resonant structures 218 to tune the optical characteristics to represent the symbols 214A-214K. In this illustrative example, the resonant structures 218A-218K are connected in series with the output of the first resonant structure 218A optically coupled to the input of a second resonant structure 218B, the output of the second resonant structure 218B optically coupled to a third resonant structure, and so on. In examples, each resonant structure 218 can be implemented as a waveguide resonator (e.g., ring resonant structure, ring filter, or the like) or other resonant structure component capable of being driven by an electronic signal to tune the performance characteristics of the resonant structures 218. In the particular example of FIG. 2, the resonant structures 218 are provided as MRRs.

In the example of FIG. 2, each resonant structure 218 can be driven to resonate at one or more resonance wavelengths of a distinct set of resonance wavelengths (e.g., each resonant structure 218 corresponds to a particular set of resonance wavelengths). In examples, each resonant structure 218 can be driven to resonate at a first resonance wavelength (λ_{i,0}) (e.g., a first resonance state), where i is an integer between 1 and k representing a respective resonant structure 218. For example, resonant structure 218A may be driven to resonate at a wavelength (λ_{1,0}), resonant structure 218B may be driven to resonate at a wavelength (λ_{2,0}), . . . , and resonant structure 218K may be driven to resonate at a wavelength (λ_{k,0}). The resonance wavelength of each resonant structure 218 may also be tuned to a second resonance wavelength (λ_{i,1}) (e.g., a second resonance state). For example, resonant structure 218A may be driven to resonate at a wavelength (λ_{1,1}), resonant structure 218B may be driven to resonate at a wavelength (λ_{2,1}), . . . , and resonant structure 218K may be driven to resonate at a wavelength (λ_{k,1}). Thus, each resonant structure 218 may be capable of resonating at a distinct set of wavelengths (e.g., a first resonance wavelength (λ_{i,0}) and a second resonance wavelength (λ_{i,1})). In some examples, a resonant structure 218 may resonate at one resonance wavelength, while in other examples a resonant structure 218 may resonate at multiple resonance wavelengths simultaneously (e.g., through multimodal waveguide properties).

In various examples, the sets of the resonance wavelengths of the resonant structures 218 may be based on the sets of resonance wavelengths of the resonant structures 216. That is, for example, the comparison engine 201 may comprise a resonant structure 218 designed for a set of resonance wavelengths that corresponds to (e.g., identical to) a set of resonance wavelengths of a resonant structure 216. As an illustrative example, resonant structures 216A and 218A may be capable of being driven to resonate at a first set of resonance wavelengths, such as the first resonance wavelength (λ_{1,0}) and/or second resonance wavelength (λ_{1,1}), depending on the operation state. Likewise, resonant structures 216B and 218B may be capable of being driven to a second set of wavelengths and so on, up to resonant structures 216K and 218K, which may be capable of being driven to a kth set of wavelengths. Thus, in examples, the integer i may represent a respective resonant structure 216 and a corresponding resonant structure 218.

In examples, resonant structures 218 comprise light-conducting medium 223A-223K, tuning components 227A-227K, and photodetectors 219A-219K (e.g., an example implementation of the one or more photodetectors 119 of FIG. 1) electrically connected to a decision circuit 209 (e.g., an example implementation of decision circuit 109 of FIG. 1). In examples, resonant structures 218 may be tuned to respective resonance wavelengths to represent symbols 214A-214K. In this case, the comparison engine 201 may be implemented as a cascaded microring modulator (MRM) circuit, which stores search word 214 through tuning of the tuning components 227A-227K. Each resonant structure 218 may be driven so to represent one of symbols 214A-214K. The photodetectors 219A-219K may be optically coupled to the resonant structures 218 to be capable of detecting an intensity of light propagating in a respective resonant structure 218 and generate an electrical signal indicative of the light intensity therein. The electrical signal can be coupled to a decision circuit 209 that can receive a current from the photodetectors 219A-219K, determine a match/mismatch based on the current, and output a memory address corresponding to the data word represented by the encoded data word signal 210.

The following description of the resonant structures 218 will be provided with respect to resonant structure 218A as an illustrative example. In the example of FIG. 2, resonant structure 218A comprises a light-conducting medium 223A optically coupled to a photodetector 219A and one or more tuning components 227A.

The light-conducting medium 223A may comprise an optical waveguide such as a semiconductor waveguide. In examples, the resonant structure 218A can be communicatively coupled to one or more tuning components 227A. The tuning component 227A may be capable of changing an optical characteristic of the resonant structures 218A to enable tuning of the performance of the resonant structure 218A. In various examples, the tuning component 227A can comprise one or more devices configured to change a refractive index of the light-conducting medium 223A, control the number of free carriers, and/or create a red and/or blue shift of a resonance wavelength of the resonant structure 218A. Tuning the resonant structure 218A may induce a wavelength shift in the light emitted by the resonant structure 218A. For example, the tuning component 227A may be driven to change the resonant structure 218A between a first resonance state during which the resonant structure 218A resonates at the first resonance wavelength (λ_{1,0}) and a second resonance state during which the resonant structure 218A resonates at the second resonance wavelength (λ_{1,1}). The tuning component 227A may be include, but is not limited to, heaters, electrical contacts, and capacitive structures, among other devices used to tune the resonance wavelength of optical components. In some examples, this tuning may be a non-volatile tuning, similar to the non-volatile tuning described below in connection with FIGS. 7A-7B, which can provide for non-volatile storage of the search word 214.

In some examples, the photodetector 219A is incorporated into a section of the light-conducting medium 223A, which may operate as an output routing element (e.g., output routing element 107) in this example. For example, the resonant structure 218A may include an absorbing structure within or adjacent to light-conducting medium 223A that can be used to detect light intensity therein. In this case, the in-situ absorbing structure generates an electrical signal indicative of the light intensity in the light-conducting medium 223A detected by the in-situ absorbing structure. Illustrative examples of absorbing structures integrated into an MRR are described, for example, in U.S. Pat. Nos. 11,442,235 and 11,927,819, each assigned to the Applicant and the disclosures of which are incorporated herein by reference.

In another example, a photodetector 219A can be optically coupled to the resonant structure 218A via a drop waveguide (e.g., an example of the output routing element 107 of FIG. 1). Light resonating in the resonant structure 218A can be optically coupled into the drop waveguide and the photodetector 219A can detect an intensity of the light on the drop waveguide. In this example, the photodetectors 219A can comprise a photodiode or other type of circuit-type detector of photons.

In examples, drivers 212A-212K (e.g., an example implementation of programming controller 112 of FIG. 1) can be used to drive the resonant structures 218 to represent the symbol positions of the search word 214. In the example of FIG. 2, each of the drivers 212A-212K can be configured to control tuning of a corresponding resonant structure 218. However, in other examples, drivers 212A-212K may be implemented as a single driver configured to control the tuning of the plurality of resonant structures 218. In some examples, the drivers 212A-212K can be operated to drive the tuning components 227A-227K so to change the optical characteristic of the respective resonant structures 218 to tune between the first resonance state and second resonance state.

The drivers 212A-212K can be communicatively coupled to the memory storing the search word (e.g., search word storage 114) and configured to retrieve a stored search word for comparing to optical signals encoded by the input encoder 202. The drivers 212A-212K can maintain a mapping of symbols 214A-214K to the resonant structures 218 in a dedicated memory component, in the data word storage, or in another separate memory component communicatively coupled to the drivers 212A-212K, or a combination thereof.

In performing an operation on the stored data word 203 encoded in accordance with Table 1, the drivers 212A-212K can be configured to tune the comparison engine 201 either to couple light of the wavelength of the encoded word or to pass the light. Table 2 illustrates an example encoding scheme in accordance with a TCAM implementation. Table 2 shows the operational state of the comparison engine 201 for each corresponding symbol value of the search word retrieved from the search word storage (e.g., search word storage 114).

TABLE 2

| Search Word | Encode Search |
|---|---|
| Symbol (sᵢ) | Word Symbol State |
| 0 | λ_{i, 1} |
| 1 | λ_{i, 0} |
| X | Detuned |

As shown in Table 2, the search word 214 can be represented by a plurality of encoded search word symbol values s₁, s₂, . . . sₖ (e.g., symbols 214A-214K in FIG. 2). To provide a search word symbol value sᵢ of logic ‘0’, a resonant structure 218 can be tuned to the second resonance wavelength (λ_{i,1}) within the search word symbol value sᵢ associated with the symbol position. As an example, resonant structure 218A can be driven to represent a logic ‘0’ by tuning the resonance of the resonant structure 218A to its second resonance wavelength (λ_{1,1}) (e.g., a second resonance state). For the stored data symbol value sᵢ of logic ‘1’, a resonant structure 218 can be tuned to the first resonance wavelength (λ_{i,0}) within the search word symbol value sᵢ associated with the symbol position. As an example, resonant structure 218A can be driven to represent a logic ‘1’ by tuning the resonance of the resonant structure 218A to its first resonance wavelength (λ_{1,0}) (e.g., a first resonance state). To provide a search word symbol value sᵢ of wildcard symbol ‘X’, a resonant structure 218 can be detuned with respect to its first resonance wavelength (λ_{i,0}) and second resonance wavelength (λ_{i,1}) within the search word symbol value sᵢ associated with the symbol position. As an example, the resonant structure 218A can be driven to represent a wildcard symbol ‘X’ by detuning the resonance of the resonant structure 218A with respect to the first wavelength (λ_{1,0}) and second wavelength (λ_{1,1}) (e.g., the resonant structure 218A can be driven to a third resonance state).

Based on the logic states indicated in Tables 1 and 2, light will couple into the resonant structures 218 for a respective encoded search symbol sᵢ when a mismatch occurs between the value of a symbol position of the data word 203 and the corresponding value of the symbol position of the search word 214. The photodetectors 219A-219K can be configured to detect the presence (or absence of light) coupled into respective resonant structures 218, thereby detecting the mismatch and/or match for a respective symbol position. The photodetectors 219A-219K generate an electrical response (e.g., a current) indicative of the intensity of light detected and supply the electrical response to the decision circuit 209. The decision circuit 209 may detect the electrical response and output a memory address corresponding to the data word represented by the encoded data word signal 210.

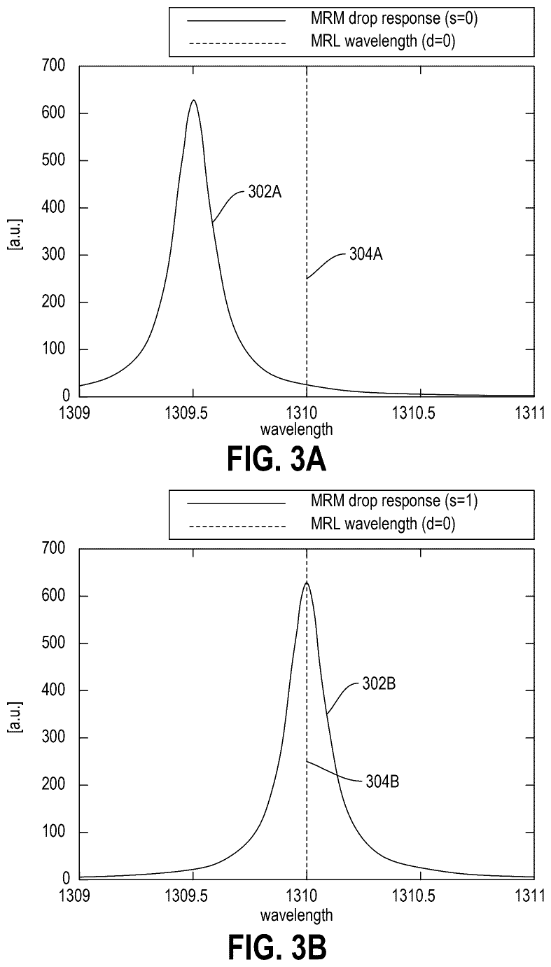

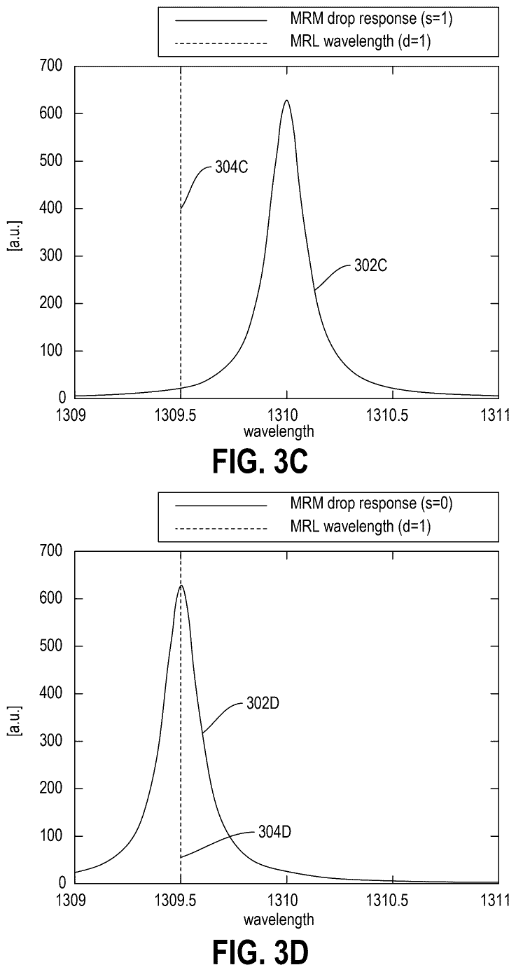

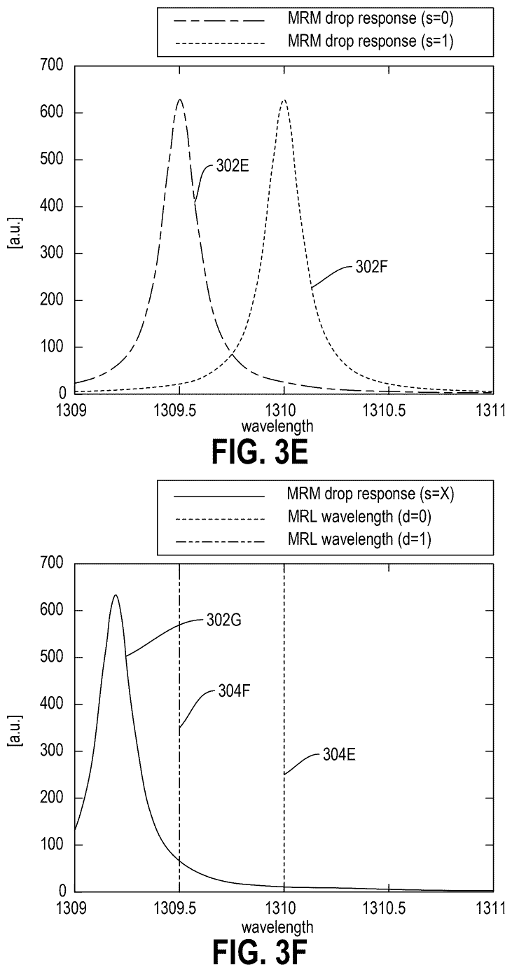

Table 3 shows the results based on the encoded symbol value of the encoded data word signal 210 and the corresponding comparison engine 201. FIGS. 3A-3F depict electromagnetic spectrums 304A-304F, respectively, of light emitted from a resonant structure 216 based on a symbol value of a data word encoded by the input encoder 202. FIGS. 3A-3F also depict optical transfer functions 302A-302F, respectively, of a resonant structure 218 based on the encoded symbol value of the encoded search word encoded by the comparison engine 201.

TABLE 3

| Search | | Data | | | |
|---|---|---|---|---|---|
| Word | Encoded | Word | Encoded | | |
| Symbol | Search Word | Symbol | Data Word | Match State | Electrical |
| (sᵢ) | Symbol State | (dᵢ) | Symbol State | (no light/light) | Response |
| 0 | λ_{i, 1} | 0 | λ_{i, 0} | Match (no light) | No current |
| 0 | λ_{i, 1} | 1 | λ_{i, 1} | Mismatch (light) | Current |
| 1 | λ_{i, 0} | 0 | λ_{i, 0} | Mismatch (light) | Current |
| 1 | λ_{i, 0} | 1 | λ_{i, 1} | Match (no light) | No current |
| X | Detuned | 0 or 1 | λ_{i, 0} or λ_{i, 1} | Match (no light) | No current |
| 0 or 1 | λ_{i, 0} or λ_{i, 1} | X | Off | Match (no light) | No current |

As shown in Table 3, when the symbol of the encoded data word is a logical ‘0’, the input (e.g., encoded data word signal 210) includes light at the first wavelength (λ_{i,0}) having an amplitude A (e.g., equal to or above a threshold amplitude A) representing the encoded data word value dᵢ of the associated symbol position. If the symbol value of the search word 214 at the corresponding symbol position is a logic ‘0’, the comparison engine 201 can be driven to resonate at the second wavelength (λ_{i,1}). Therefore, because the comparison engine 201 is configured to resonate at a wavelength that is different from the input, the light on the input routing element 204B does not couple into a respective resonant structure 218 and permitted to pass through the comparison engine 201 to a terminator 230. Accordingly, the lack of light, as shown in FIG. 3A, indicates that the symbol dᵢ of the data word 203 and the symbol sᵢ of the search word 214 at the respective symbol position are matched.

As an illustrative example, when the symbol 203A is a logical ‘0’, resonant structure 216A can be tuned, via driver 206A operating light emitting device 215A and tuning component 217A, to the first on state so to emit light at the first wavelength (λ_{1,0}) having an amplitude A (e.g., equal to or above a threshold amplitude A) representing the encoded data word value d₁ of the associated symbol position. The emitted light can be coupled into the input routing element 204A and supplied to the comparison engine 201 via input routing element 204B. If the symbol 214A is a logic ‘0’, resonant structure 218A can be tuned, via driver 212A operating tuning component 227A, to the second resonance state so to resonate at the second wavelength (λ_{1,1}). Because the resonance wavelength of resonant structure 218A differs from that of the encoded data word signal 210 at the symbol 214A, no light (or light below the threshold amplitude A) is coupled from the input routing element 204B into resonant structure 218A and the photodetector 219A does not detect an intensity of light at or above the threshold amplitude. Thus, the electrical response generated by the photodetector 219A is below a threshold current amplitude and is detected by the decision circuit 209 as “no current” representative of a matched state.

However, if the symbol value of the search word at the corresponding symbol position is a logic ‘1’, the comparison engine 201 can be driven to a first resonance state so to resonate at the first wavelength (λ_{i,0}). Therefore, because the comparison engine 201 is configured to resonate at the wavelength of the input, the light on the input routing element 204B couples into a respective resonant structure 218 and is detected by a respective photodetector. Accordingly, the presence of light, as shown in FIG. 3B, indicates that the symbol dᵢ of the data word 203 and the symbol sᵢ of the search word 214 at the respective symbol position are mismatched.

Returning to the above illustrative example, to represent symbol 214A as a logic ‘1’, resonant structure 218A can be tuned to the first resonance state so to resonate at the first wavelength (λ_{1,0}). Because the resonance wavelength of resonant structure 218A is the same as that of the encoded data word signal 210 at the symbol 214A, light (e.g., light at or above the threshold amplitude A) is coupled from the input routing element 204B into resonant structure 218A and the photodetector 219A detects the intensity of light. Thus, the electrical response generated by the photodetector 219A is above a threshold current amplitude and is detected by the decision circuit 209 as “current” representative of a mismatched state.

When the symbol of the encoded data word is a logical ‘1’, the input (e.g., encoded data word signal 210) includes light at the second wavelength (λ_{i,1}) having an amplitude A (e.g., equal to or above a threshold amplitude A) representing the encoded data word value dᵢ of the associated symbol position (e.g., resonant structure 216A can be tuned to the second on state to emit light at the second wavelength (λ_{1,1})). If the symbol value of the search word 214 at the corresponding symbol position is a logic ‘1’, the comparison engine 201 can be driven to the first resonance state to resonate at the first wavelength (λ_{i,0}) (e.g., resonant structure 218A can be driven to resonate at the first wavelength (λ_{1,0})). Therefore, because the comparison engine 201 is configured to resonate at a wavelength that is different from the input, the light on the input routing element 204B does not couple into a respective resonant structure 218 and is permitted to pass through the comparison engine 201 to terminator 230 (e.g., the resonance wavelength of resonant structure 218A differs from that of the encoded data word signal 210 at the symbol 214A and no light or light below the threshold amplitude A is coupled into resonant structure 218A and photodetector 219A does not detect an intensity of light at or above the threshold amplitude). Accordingly, the lack of light, as shown in FIG. 3C, indicates that the symbol dᵢ of the data word 203 and the symbol sᵢ of the search word 214 at the respective symbol position are matched.

However, if the symbol value of the search word at the corresponding symbol position is a logic ‘0’, the comparison engine 201 can be driven to the second resonance state so to resonate at the second wavelength (λ_{i,1}) (e.g., resonant structure 218A can be driven to resonate at the second wavelength (λ_{1,1})). Therefore, because the comparison engine 201 is configured to pass light, the light on the input routing element 204B couples into a respective resonant structure 218 and is detected by a respective photodetector (e.g., the resonance wavelength of resonant structure 218A is the same as that of the encoded data word signal 210 at the symbol 214A and light at or above the threshold amplitude A is coupled into resonant structure 218A and photodetector 219A detects the intensity of light). Accordingly, the presence of light, as shown in FIG. 3D, indicates that the symbol dᵢ of the data word 203 and the symbol sᵢ of the search word 214 at the respective symbol position are mismatched.

When the symbol of the encoded data word is a wildcard ‘X’, the input can be turned off (e.g., light at the input routing element 204A is below the threshold amplitude A) representing the encoded data word value dᵢ of the associated symbol position (e.g., resonant structure 216A can be tuned to the off state during which no light or light below the threshold amplitude A is emitted). In this case, the symbol value of the search word 214 at the corresponding symbol position can be a logic ‘1’ or logic ‘0’ (as well as a wildcard state or any state for that matter), in which the comparison engine 201 can be driven to the first or second resonance state (or any state) (e.g., resonant structure 218A can be tuned to any state). Therefore, because there is no light on the input routing element 204B (or any light thereon is below the threshold amplitude A), no light is coupled into a respective resonant structure 218. Accordingly, the lack of light (or light below the threshold amplitude A), as shown in FIG. 3E, indicates a match.

When the symbol of the search word 214 is a wildcard ‘X’, the comparison engine 201 be detuned relative to the first wavelength (λ_{i,0}) and second wavelength (λ_{i,1}) (e.g., resonant structure 218A can be detuned relative to the first wavelength (λ_{1,0}) and second wavelength (λ_{1,1})). In this case, the input (e.g., encoded data word signal 210) can include light at either the first or second wavelengths having an amplitude A (e.g., equal to or above a threshold amplitude A) representing encoded data word value dᵢ of the associated symbol position (e.g., resonant structure 216A is tuned to the first or second on state). Therefore, because the comparison engine 201 is detuned relative to the wavelengths of light on the input routing element 204B, the light on the input routing element 204B does not couple into a respective resonant structure 218 and is permitted to pass through the comparison engine 201 to terminator 230 (e.g., the resonance wavelength of resonant structure 218A differs from that of the encoded data word signal 210 at the symbol 214A and no light or light below the threshold amplitude A is coupled into resonant structure 218A and photodetector 219A does not detect an intensity of light at or above the threshold amplitude). Accordingly, the lack of light, as shown in FIG. 3F, indicates that the symbol dᵢ of the data word 203 and the symbol sᵢ of the search word 214 at the respective symbol position are matched.

While the above examples are discussed with respect to TCAM encoding schemes, the examples herein may also be applicable to other CAM encoding schemes. For example, Table 4 illustrates an example encoding scheme for encoding a data word in accordance with a QCAM implementation of the technology disclosed herein. The QCAM implementation leverages the multimodal property of a multimodal waveguide. That is, for example, the light-conducting medium 223A-223K of the resonant structures 218 may comprise multimodal waveguides capable of resonating two or more resonance wavelengths simultaneously, such as the first and second wavelengths.

TABLE 4

| Data Word | Encode Stored Data |
|---|---|
| Symbol Value (dᵢ) | Word Symbol State |
| 0 | λ_{i, 0} |
| 1 | λ_{i, 1} |
| X | Off |
| ρ | λ_{i, 0} and λ_{i, 1} |

Table 4 includes the encoding scheme of Table 1 and adds the reject symbol “ρ.” To provide a data word symbol value dᵢ of logic ‘0’, logic ‘1’, or the wildcard value “X”, the input encoder 202 can be driven as described above in connection with Table 1. To provide a stored data word symbol value dᵢ of reject symbol ‘ρ’, light having an amplitude A can be transmitted at the first wavelength (λ_{i,0}) and second wavelength (λ_{i,1}), simultaneously, within the data word symbol value dᵢ associated with the symbol position. For example, resonant structure 216A can be driven to represent a reject symbol ‘ρ’ by turning on the light emitting device 215A to the on state and driving the one or more tuning components 217A to tune the resonant structure 216A to a third on state, during which the resonant structure 216A emits light at both of the first and second wavelengths (λ_{1,0} and λ_{1,1}). In examples, the resonant structure 216A may emit light at two wavelengths by designing the resonant structure 216A to have two optical modes, for example, in the case of a single MRR configuration.

In another example, each resonant structure 216 may comprise two cascaded MMRs. For example, two MRRs may be optically coupled to each other and one of the two MRRs may be coupled to the input routing element 204A. As another example, the two MRRs may be respectively coupled to the input routing element 204A. In either case, each MRR may be comprise its own light emitting device and tuning component, as described above, which may be used to tune the MRR to a respective wavelength. As such the two MRRs, which constitute a resonant structure 216, can be operated to emit light at two wavelengths (λ_{1,0} and λ_{1,1}).

Table 5 illustrates an example encoding scheme for encoding a search word in accordance with a QCAM implementation of the technology disclosed herein.

TABLE 5

| Search Word | Encode Search |
|---|---|
| Symbol (sᵢ) | Word Symbol State |
| 0 | λ_{i, 1} |
| 1 | λ_{i, 0} |
| X | Detuned |
| ρ | λ_{i, 0} and λ_{i, 1} |

Table 5 includes the encoding scheme of Table 2 and adds the reject symbol “ρ.” To provide a search word symbol value sᵢ of logic ‘0’, logic ‘1’, or the wildcard value “X”, the comparison engine 201 can be driven as described above in connection with Table 2. To provide a search word symbol value sᵢ of reject value ‘ρ’, the comparison engine 201 can be tuned to the first wavelength (λ_{i,0}) and the second wavelength (λ_{i,1}) within the search word symbol value sᵢ associated with the symbol position. For example, the resonant structure 218A can be driven to represent a reject symbol ‘ρ’ by tuning the resonance of the resonant structure 218A, via the one or more tuning components 227A, to the first wavelength (λ_{1,0}) and second wavelength (λ_{1,1}) (e.g., the first and second resonance state).

Table 6 shows the results based on the encoded symbol value of the encoded data word signal 210 and of the corresponding comparison engine 201 according to the QCAM implementation discussed above.

TABLE 6

| Search | | Data | | | |
|---|---|---|---|---|---|
| Word | Encoded | Word | Encoded | | |
| Symbol | Search Word | Symbol | Data Word | Match State | Electrical |
| (sᵢ) | Symbol State | (dᵢ) | Symbol State | (no light/light) | Response |
| 0 | λ_{i, 1} | 0 | λ_{i, 0} | Match (no light) | No current |
| 0 | λ_{i, 1} | 1 | λ_{i, 1} | Mismatch (light) | Current |
| 0 | λ_{i, 1} | X | Off | Match (no light) | No current |
| 0 | λ_{i, 1} | ρ | λ_{i, 0} and λ_{i, 1} | Mismatch (light) | Current |
| 1 | λ_{i, 0} | 0 | λ_{i, 0} | Mismatch (light) | Current |
| 1 | λ_{i, 0} | 1 | λ_{i, 1} | Match (no light) | No current |
| 1 | λ_{i, 0} | X | Off | Match (no light) | No current |
| 1 | λ_{i, 0} | ρ | λ_{i, 0} and λ_{i, 1} | Mismatch (light) | Current |
| X | Detuned | 0 | λ_{i, 0} | Match (no light) | No current |
| X | Detuned | 1 | λ_{i, 1} | Match (no light) | No current |
| X | Detuned | X | Off | Match (no light) | No current |
| X | Detuned | ρ | λ_{i, 0} and λ_{i, 1} | Match (no light) | No current |
| ρ | λ_{i, 0} and λ_{i, 1} | 0 | λ_{i, 0} | Mismatch (light) | Current |
| ρ | λ_{i, 0} and λ_{i, 1} | 1 | λ_{i, 1} | Mismatch (light) | Current |
| ρ | λ_{i, 0} and λ_{i, 1} | X | Off | Match (no light) | No current |
| ρ | λ_{i, 0} and λ_{i, 1} | ρ | λ_{i, 0} and λ_{i, 1} | Mismatch (light) | Current |

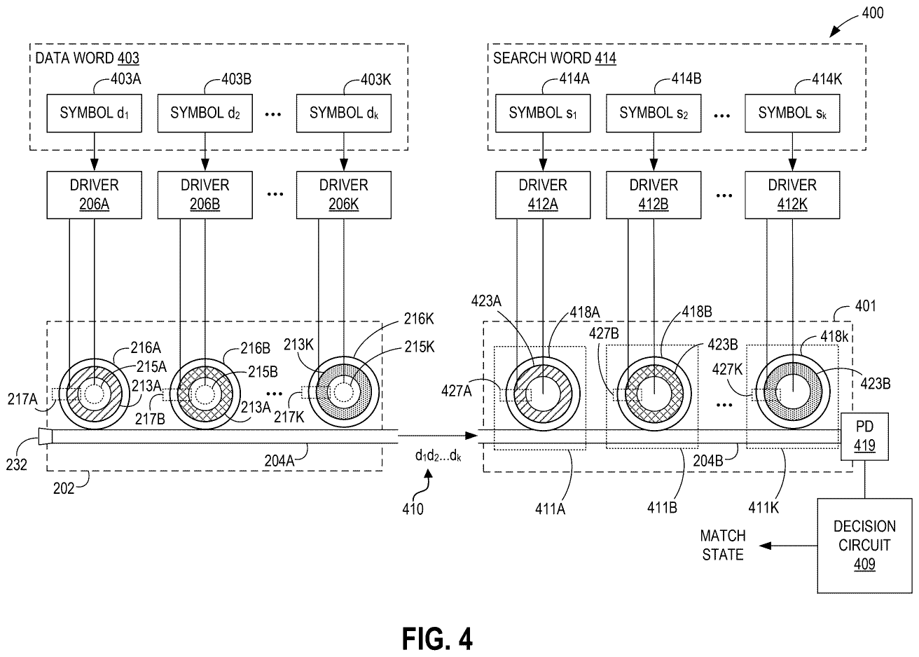

FIG. 4 is an optical search engine 400 in accordance another example of the present disclosure. The optical search engine 400, in this example, may be implemented to perform WDM O-CAM in accordance with the examples herein. The optical search engine 400 is provided for illustrative purposes only and should not be interpreted as limiting the scope of the disclosed technology to only the depicted example. In examples, optical search engine 400 may be implemented to compare a data word 403 represented as symbols 403A-403K and a search word 414 represented as symbols 414A-414K through the use of input encoder 202 (e.g., the input encoder of optical search engine 400 may be the same as the input encoder of optical search engine 200 described above) and a comparison engine 401. In various examples, optical search engine 400 performs the comparison optically using data words and search words that can be stored in a memory, such as data word storage 108 and search word storage 114 of FIG. 1, respectively.

In the example of FIG. 4, the input encoder 202 is optically coupled to a comparison engine 401 through input routing elements 204A and 204B. The optical search engine 400 compares the data word 403 and the search word 414 through the input encoder 202 and the comparison engine 401. Since the input encoder of optical search engine 400 can be implemented as input encoder 202, the above description of input encoder 202 applies hereto and Table 1 illustrates an example encoding scheme in accordance with a TCAM implementation of the technology disclosed herein.

As shown in FIG. 4, data word 403 can be received by the input encoder 202 as a plurality of symbols 403A-403K, each corresponding to an encoded data word symbol values d₁, d₂, . . . dₖ. The data word symbols 403A-403K can be encoded by driving a plurality of resonant structures 216A-216K as described above to generate and output an encoded data word signal 410, similar to the encoding encoded data word signal 210 discussed with respect to FIG. 2. For example, an encoded data word signal 410 can comprise k optical signals, each of which is encoded with data word symbol values according to encoding scheme of Table 1, where k is the number of symbol positions in the stored data word D.

The encoded data word signal 210 generated by the input encoder 202 can be provided to comparison engine 401, for example, through input routing elements 204A and 204B, as described above in connection with FIG. 2.

To perform a search operation, the comparison engine 401 can be driven to store search word 414, in some examples. In the example of FIG. 4, the comparison engine 401, in some examples, can include one or more O-CAM cells 411A-411K. The O-CAM cells 411A-411K may comprise resonant structures 418A-418K (e.g., example implementations of one or more resonant structures 118) that can be tuned to store search word symbols 414A-414K. The resonant structures 418A-418K (collectively referred to herein as resonant structures 418 or singularly as resonant structure 418) may be driven by an electronic signal to tune optical characteristics of the resonant structures 418. The symbols 414A-414K of search word 414 may be stored in each O-CAM cell by driving the plurality of resonant structures 418 to tune the optical characteristics to represent the symbols 414A-414K. In this illustrative example, the resonant structures 418A-418K are connected in series. In examples, each resonant structure 418 can be implemented as a waveguide resonator (e.g., MRR, ring filter, or the like) or other resonating component capable of being driven by an electronic signal to tune the performance characteristics of the resonant structures 418. In the particular example of FIG. 4, the resonant structures 418 are provided as MRRs.

In the example of FIG. 4, each resonant structure 418 can be driven to resonate at one or more resonance wavelengths of a distinct set of resonance wavelengths (e.g., each resonant structure 418 corresponds to a particular set of resonance wavelengths). In examples, each resonant structure 418 can be driven to resonate at a first resonance wavelength (λ_{i,0}) (e.g., a first resonance state), where i is an integer between 1 and k representing a respective resonant structure 418. For example, resonant structure 418A may be driven to resonate at a wavelength (λ_{1,0}), resonant structure 418B may be driven to resonate at a wavelength (λ_{2,0}), . . . , and resonant structure 418K may be driven to resonate at a wavelength (λ_{k,0}). The resonance wavelength of each resonant structure 418 may also be tuned to a second resonance wavelength (λ_{i,1}) (e.g., a second resonance state). Thus, each resonant structure 418 may be capable of resonating at a distinct set of wavelengths (e.g., a first resonance wavelength (λ_{i,0}) and a second resonance wavelength (λ_{i,1})). In some examples, a resonant structure 418 may resonate at one resonance wavelength, while in other examples a resonant structure 418 may resonate at multiple resonance wavelengths simultaneously (e.g., through multimodal waveguide properties).

In various examples, the sets of the resonance wavelengths of the resonant structures 418 may be based on the sets of resonance wavelengths of the resonant structures 216. That is, for example, the comparison engine 401 may comprise a resonant structure 418 designed for a set of resonance wavelengths that corresponds to (e.g., is the identical to) a set of resonance wavelengths of a resonant structure 216. As an illustrative example, resonant structures 216A and 418A may be capable of being driven to resonate at a first set of resonance wavelengths, such as the first resonance wavelength (λ_{1,0}) and/or second resonance wavelength (λ_{1,1}), depending on the operation state. Likewise, resonant structures 216B and 418B may be capable of being driven to a second set of wavelengths and so on, up to resonant structures 216K and 418K, which may be capable of being driven to a kth set of wavelengths. Thus, in examples, the integer i may represent a respective resonant structure 216 and a corresponding resonant structure 418.

In examples, resonant structures 418 comprise light-conducting medium 423A-423K and tuning components 427A-427K. In examples, resonant structures 418 may be tuned to respective resonance wavelengths to represent symbols 414A-414K. In this case, the comparison engine 401 may be implemented as a cascaded microring resonant structure (MRM) circuit, which stores search word 414 through tuning of the tuning components 427A-427K. Each resonant structure 418 may be driven so to represent one of symbols 414A-414K. The resonant structures 418 may be configured to operate as wavelength filters by extracting light on the input routing element 204B (e.g., coupling light from the input routing element 204B) based on tuned resonance state and permitting other wavelengths to pass to a photodetectors 419 coupled to an output end of input routing element 204B. The photodetector 419 may be capable of detecting an intensity of light on the input routing element 204B and generate an electrical signal indicative of the light intensity therein. The electrical signal can be coupled to a decision circuit 409 that can receive a current from the photodetector 419, determine a match/mismatch based on the current, and output a memory address corresponding to the data word represented by the encoded data word signal 410.

The following description of the resonant structures 418 will be provided with respect to resonant structure 418A as an illustrative example. In the example of FIG. 4, resonant structure 418A comprises a light-conducting medium 423A optically coupled to one or more tuning components 427A.

The light-conducting medium 423A may comprise an optical waveguide such as a semiconductor waveguide. In examples, the resonant structure 418A can be communicatively coupled to one or more tuning components 427A. The tuning component 427A may be capable of changing an optical characteristic of the resonant structures 418A to enable tuning of the performance of the resonant structure 418A (e.g., similar to the one or more tuning components 227A-227K of FIG. 2). In various examples, the tuning component 427A can comprise one or more devices configured to change a refractive index of the light-conducting medium 423A, control the number of free carriers, and/or create a red and/or blue shift of a resonance wavelength of the resonant structure 418A. Tuning the resonant structure 418A may induce a wavelength shift in the light emitted by the resonant structure 418A. For example, the tuning component 427A may be driven to change the resonant structure 418A between a first resonance state during which the resonant structure 418A resonates at the first resonance wavelength (λ_{1,0}) and a second resonance state during which the resonant structure 418A resonates at the second resonance wavelength (λ_{1,1}). The tuning component 427A may be include, but is not limited to, heaters, electrical contacts, and capacitive structures, among other devices used to tune the resonance wavelength of optical components. In some examples, this tuning may be a non-volatile tuning, similar to the non-volatile tuning described below in connection with FIGS. 7A-7B, which can provide for non-volatile storage of the search word 414.

In the example of FIG. 4, the tuning component 427A may also be driven to change the Quality (Q) value the resonant structure 418A so to switch between a first Q value state and a second Q value state, where the first Q-value state is higher than the second Q value state. The first Q-value state and second Q-value may be referred to herein as high-Q value and low-Q value, respectively. For example, the tuning component 427A can comprise one or more devices configured to change the propagation loss of the light-conducting medium 423A by controlling the number of free carriers near or within the light-conducting medium 423A. By controlling the number of free carriers (e.g., the charge therein), the propagation loss can be tuned between a high-Q value state (e.g., low loss) and a low-Q value state (e.g., high loss). For example, increasing the number of free carriers near or within the light-conducting medium 423A can cause a decrease in the Q-value.

During the high-Q value state, the resonant structure 418A can resonate at the first resonance wavelength (λ_{1,0}) or the second resonance wavelength (λ_{1,1}). In this state, the resonant structure 418A can extract light at either of the first resonance wavelength (λ_{1,0}) or the second resonance wavelength (λ_{1,1}) present on the input routing element 204B via optical coupling. Thus, the resonant structure 418A operates as a first band-stop filter having a first bandwidth that filters either of the first resonance wavelength (λ_{1,0}) or the second resonance wavelength (λ_{1,1}) from the input routing element 204B.

During the low-Q value state, the resonant structure 418A can resonate at a wavelength between the first resonance wavelength (λ_{1,0}) and the second resonance wavelength (λ_{1,1}). For example, the resonant structure 418A may resonate at an average of the first resonance wavelength (λ_{1,0}) and the second resonance wavelength (λ_{1,1}) (e.g., Avg (λ_{i,0}, A_{i,1})). In this state, the resonant structure 418A can extract light propagating at the first resonance wavelength (λ_{1,0}) and the second resonance wavelength (λ_{1,1}) present on the input routing element 204B via optical coupling. Thus, the resonant structure 418A operates as a second band-stop filter having a second bandwidth that filters both of the first resonance wavelength (λ_{1,0}) or the second resonance wavelength (λ_{1,1}) from the input routing element 204B. The second bandwidth may be wider than the first.

In examples, drivers 412A-412K (e.g., an example implementation of programming controller 112 of FIG. 1) can be used to drive the resonant structures 418 to represent the symbol positions of the search word 414. In the example of FIG. 4, each of the drivers 412A-412K can be configured to control tuning of a corresponding resonant structure 418. However, in other examples, drivers 412A-412K may be implemented as a single driver configured to control the tuning of the plurality of resonant structures 418. In some examples, the drivers 412A-412K can be operated to drive the tuning components 427A-427K so to change the optical characteristic of the respective resonant structures 418 to tune between the first resonance state and second resonance state, as well as the high-Q and low-Q value states.

The drivers 412A-412K can be communicatively coupled to the memory storing the search word (e.g., search word storage 114) and configured to retrieve a stored search word for comparing to optical signals encoded by the input encoder 202. The drivers 412A-412K can maintain a mapping of symbols 414A-414K to the resonant structures 418 in a dedicated memory component, in the data word storage, or in another separate memory component communicatively coupled to the drivers 412A-412K, or a combination thereof.

In performing an operation on the stored data word 403 encoded in accordance with Table 1, the drivers 412A-412K can be configured to tune the comparison engine 401 to either filter (e.g., block) light of the wavelength of the encoded word or pass the light to photodetector 419. Table 7 illustrates an example encoding scheme in accordance with a TCAM implementation. Table 7 shows the operational state of the comparison engine 401 for each corresponding symbol value of the search word retrieved from the search word storage 414.

TABLE 7

| Search Word | Encode Search |
|---|---|
| Symbol (sᵢ) | Word Symbol State |
| 0 | λ_{i, 0} (high-Q value) |
| 1 | λ_{i, 1} (high-Q value) |
| X | Avg(λ_{i, 0}, λ_{i, 1}) (low-Q value) |

As shown in Table 7, the search word 414 can be represented by a plurality of encoded search word symbol values s₁, s₂, . . . sₖ (e.g., symbols 414A-414K in FIG. 4). To provide a search word symbol value sᵢ of logic ‘0’, a resonant structure 418 can be tuned to a high-Q value state and to resonate at the first wavelength (λ_{i,0}) within the search word symbol value sᵢ associated with the symbol position. For the search word symbol value sᵢ of logic ‘1’, a resonant structure 418 can be tuned to a high-Q value state and to resonate at the second resonance wavelength (λ_{i,1}) within the search word symbol value sᵢ associated with the symbol position. To provide a search word symbol value sᵢ of wildcard symbol ‘X’, a resonant structure 418 can be tuned to the low-Q value state so to block the first resonance wavelength (λ_{i,0}) and second resonance wavelength (λ_{i,1}) within the search word symbol value sᵢ associated with the symbol position. For example, resonant structure 418 can be tuned to the low-Q value state and to resonate at the average of the first resonance wavelength (λ_{i,0}) and second resonance wavelength (λ_{i,1}).

Based on the logic states indicated in Tables 1 and 7, the resonant structures 418 will filter light from the input routing element 204B for a respective encoded search symbol sᵢ when a match occurs between the value of a symbol position of the data word 203 and the corresponding value of the symbol position of the search word 414. When a mismatch occurs, light will pass through the resonant structures 418 and be received by the photodetector 419. The photodetector 419 can be configured to detect the presence (or absence of light) on the input routing element 204B, thereby detecting the mismatch and/or match for a respective symbol position. The photodetector 419 generates an electrical response (e.g., a current) indicative of the intensity of light detected and supplies the electrical response to the decision circuit 409. The decision circuit 409 may detect the electrical response and output a memory address corresponding to the data word represented by the encoded data word signal 210.

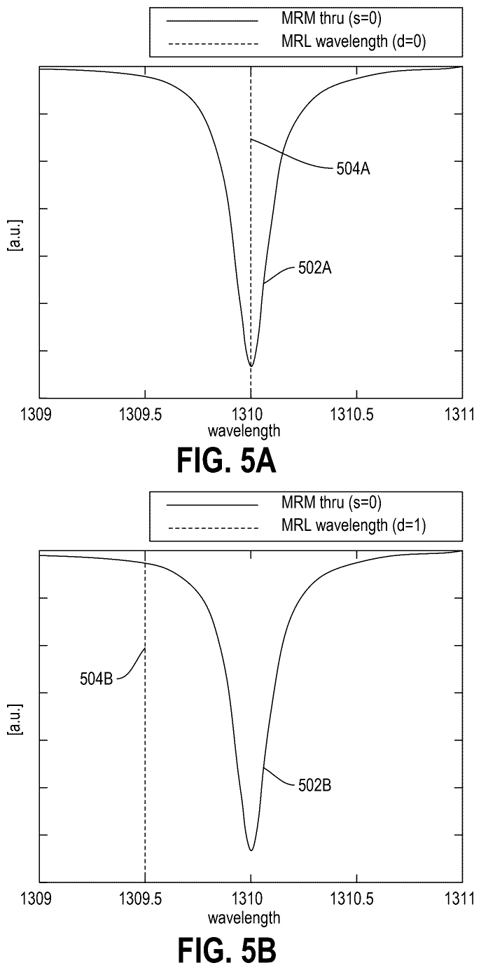

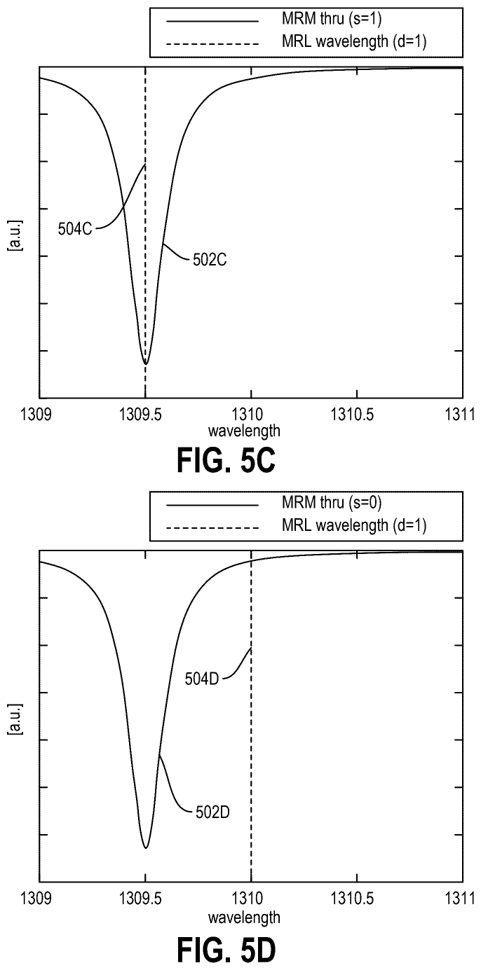

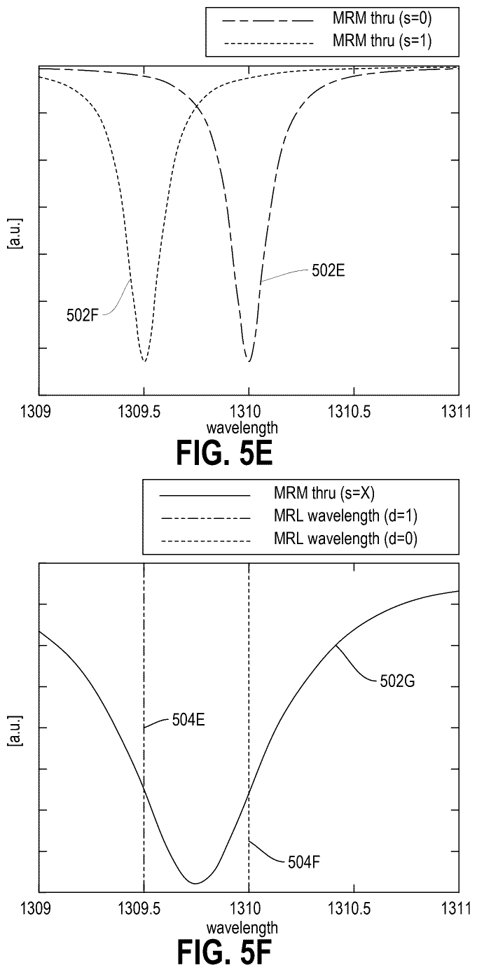

Table 8 shows the results based on the encoded symbol value of the encoded data word signal 210 and of the corresponding comparison engine 401. FIGS. 5A-5F depict electromagnetic spectrums 504A-504F, respectively, of light emitted from a resonant structure 216 based on a symbol value of a data word encoded by the input encoder 202. FIGS. 5A-5F also depict optical transfer functions 502A-502F, respectively, of a resonant structure 418 based on the encoded symbol value of the encoded search word encoded by the comparison engine 401.

TABLE 8

| Search | | Data | | | |
|---|---|---|---|---|---|
| Word | Encoded | Word | Encoded | | |
| Symbol | Search Word | Symbol | Data Word | Match State | Electrical |
| (sᵢ) | Symbol State | (dᵢ) | Symbol State | (filtered/passed) | Response |
| 0 | λ_{i, 0} | 0 | λ_{i, 0} | Match (filtered) | No current |
| | (high-Q value) | | | | |
| 0 | λ_{i, 0} | 1 | λ_{i, 1} | Mismatch (passed) | Current |
| | (high-Q value) | | | | |
| 1 | λ_{i, 1} | 0 | λ_{i, 0} | Mismatch (passed) | Current |
| | (high-Q value) | | | | |
| 1 | λ_{i, 1} | 1 | λ_{i, 1} | Match (filtered) | No current |
| | (high-Q value) | | | | |
| X | Avg(λ_{i, 0}, λ_{i, 1}) | 0 or 1 | λ_{i, 0} or λ_{i, 1} | Match (filtered) | No current |
| | (low-Q value) | | | | |
| 0 or 1 | λ_{i, 0} or λ_{i, 1} | X | Off | Match (filtered) | No current |

As shown in Table 8, when the symbol of the encoded data word is a logical ‘0’, the input (e.g., encoded data word signal 210) includes light at the first wavelength (λ_{i,0}) having an amplitude A (e.g., equal to or above a threshold amplitude A) representing the encoded data word value dᵢ of the associated symbol position. If the symbol value of the search word 414 at the corresponding symbol position is a logic ‘0’, the comparison engine 401 be driven the high-Q value state and to resonate at the first wavelength (λ_{i,0}) (e.g., resonant structure 216A is driven to emit light at the first wavelength (λ_{i,0}) and resonant structure 418A is driven to the high-Q value state and resonates at the first wavelength (λ_{i,0})). Therefore, because the comparison engine 401 is configured to resonate at the same wavelength as the input, the light on the input routing element 204B is filtered from the input routing element 204B due to coupling into a respective resonant structure 418. Accordingly, the lack of light at the photodetector 419 (e.g., light below the threshold amplitude A), as shown in FIG. 5A, indicates that the symbol dᵢ of the data word 203 and the symbol sᵢ of the search word 414 at the respective symbol position are matched.

However, if the symbol value of the search word at the corresponding symbol position is a logic ‘1’, the comparison engine 401 can be driven to the second resonance state so to resonate at the second wavelength (λ_{i,1}) (e.g., resonant structure 418A is driven to the high-Q value state and resonates at the second wavelength (λ_{i,1}). Therefore, because the comparison engine 401 is configured to resonate at a wavelength that is different from that of the input, the light on the input routing element 204B is permitted to pass and is detected by the photodetector 419. Accordingly, the presence of light (e.g., light at or above the threshold amplitude A), as shown in FIG. 5B, indicates that the symbol dᵢ of the data word 203 and the symbol sᵢ of the search word 414 at the respective symbol position are mismatched.

When the symbol of the encoded data word is a logical ‘1’, the input (e.g., encoded data word signal 210) includes light at the second wavelength (λ_{i,1}) having an amplitude A (e.g., equal to or above a threshold amplitude A) representing the encoded data word value dᵢ of the associated symbol position (e.g., resonant structure 216A can be tuned to the second on state to emit light at the second wavelength (λ_{1,1})). If the symbol value of the search word 414 at the corresponding symbol position is a logic ‘1’, the comparison engine 401 can be driven to high-Q value state and to the second resonance state to resonate at the second wavelength (λ_{i,1}) (e.g., resonant structure 418A can be driven to high-Q value state and to resonate at the second wavelength (λ_{1,1})). Therefore, because the comparison engine 401 is configured to resonate at a wavelength is the same as the input, the light on the input routing element 204B is filtered from the input routing element 204B. Accordingly, the lack of light at the photodetector 419 (e.g., light below the threshold amplitude A), as shown in FIG. 5C, indicates that the symbol dᵢ of the data word 203 and the symbol sᵢ of the search word 414 at the respective symbol position are matched.

However, if the symbol value of the search word 414 at the corresponding symbol position is a logic ‘0’, the comparison engine 401 can be driven to the first resonance state so to resonate at the first wavelength (λ_{i,0}) (e.g., resonant structure 418A can be driven to the high-Q value state and to resonate at the first wavelength (λ_{1,0})). Therefore, because the comparison engine 401 is configured to resonate at a wavelength that is different from that of the input, the light on the input routing element 204B is permitted to pass and is detected by the photodetector 419. Accordingly, the presence of light (e.g., light at or above the threshold amplitude A), as shown in FIG. 5D, indicates that the symbol dᵢ of the data word 203 and the symbol sᵢ of the search word 414 at the respective symbol position are mismatched.

When the symbol of the encoded data word is a wildcard ‘X’, the input can be turned off (e.g., light at the input routing element 204A is below the threshold amplitude A) representing the encoded data word value dᵢ of the associated symbol position (e.g., resonant structure 216A can be tuned to the off state during which no light or light below the threshold amplitude A is emitted). In this case, the symbol value of the search word 414 at the corresponding symbol position can be a logic ‘1’ or logic ‘0’ (as well as a wildcard state or any state for that matter), in which the comparison engine 401 can be driven to the first or second resonance state (or any state) (e.g., resonant structure 418A can be tuned to any state). Therefore, because there is no light on the input routing element 204B (or any light thereon is below the threshold amplitude A), as shown in FIG. 5E, no light is passed to the photodetector 419. Accordingly, the lack of light (or light below the threshold amplitude A) indicates a match.

When the symbol of the search word 414 is a wildcard ‘X’, the comparison engine 401 can be driven to the low-Q value state and resonate to block the first wavelength (λ_{i,0}) and second wavelength (λ_{i,1}). In an example, resonant structure 418A can be tuned to the average of the first wavelength (λ_{1,0}) and second wavelength (λ_{1,1}). In this case, the input (e.g., encoded data word signal 210) can include light at either the first or second wavelengths having an amplitude A (e.g., equal to or above a threshold amplitude A) representing encoded data word value dᵢ of the associated symbol position (e.g., resonant structure 216A is tuned to the first or second on state). Therefore, because the comparison engine 401 is tuned to block the first and second wavelengths, any light at the first and second wavelengths may be partially coupled into a respective resonant structure, thereby partially filtering the light on the input routing element 204B and permitting attenuated light (e.g., reduced amplitude) at the first and/or second wavelengths to pass to the photodetector 419 with a reduced amplitude. The attenuated light may have an amplitude that is below the threshold amplitude A, such that the light detected by the photodetector 419 is negligible. Accordingly, the detection of light below the threshold amplitude A, as shown in FIG. 5F, indicates that the symbol dᵢ of the data word 203 and the symbol sᵢ of the search word 414 at the respective symbol position are matched. FIG. 5F also illustrates that the bandwidth of the optical transfer function 502G, which represents the second bandwidth of a band-stop filter implemented by the resonant structure 418A in this example, is wider than the bandwidth of the optical transfer functions 502A-502F.

While the above examples are discussed with respect to TCAM encoding schemes, the example of FIG. 4 may also be applicable to other CAM encoding schemes. For example, Table 9 illustrates an example encoding scheme for encoding a data word in accordance with a QCAM implementation of the technology disclosed herein. The QCAM implementation leverages the multimodal property of a multimodal waveguide. That is, for example, the light-conducting medium 423A-423K of the resonant structures 418 may comprise multimodal waveguides capable of resonating two or more resonance wavelengths simultaneously, such as the first and second wavelengths.

TABLE 9

| Search | | Data | | | |
|---|---|---|---|---|---|
| Word | Encoded | Word | Encoded | | |
| Symbol | Search Word | Symbol | Data Word | Match State | Electrical |
| (sᵢ) | Symbol State | (dᵢ) | Symbol State | (filtered/passed) | Response |
| 0 | λ_{i, 0} | 0 | λ_{i, 0} | Match (filtered) | No current |
| | (high-Q value) | | | | |
| 0 | λ_{i, 0} | 1 | λ_{i, 1} | Mismatch (passed) | Current |
| | (high-Q value) | | | | |
| 0 | λ_{i, 0} | X | Off | Match (filtered) | No current |
| | (high-Q value) | | | | |
| 0 | λ_{i, 0} | ρ | λ_{i, 0} and λ_{i, 1} | Mismatch (passed) | Current |
| | (high-Q value) | | | | |
| 1 | λ_{i, 1} | 0 | λ_{i, 0} | Mismatch (passed) | Current |
| | (high-Q value) | | | | |
| 1 | λ_{i, 1} | 1 | λ_{i, 1} | Match (filtered) | No current |
| | (high-Q value) | | | | |
| 1 | λ_{i, 1} | X | Off | Match (filtered) | No current |
| | (high-Q value) | | | | |
| 1 | λ_{i, 1} | ρ | λ_{i, 0} and λ_{i, 1} | Mismatch (passed) | Current |
| | (high-Q value) | | | | |
| X | Avg(λ_{i, 0}, λ_{i, 1}) | 0 | λ_{i, 0} | Match (filtered) | No current |
| | (low-Q value) | | | | |
| X | Avg(λ_{i, 0}, λ_{i, 1}) | 1 | λ_{i, 1} | Match (filtered) | No current |
| | (low-Q value) | | | | |
| X | Avg(λ_{i, 0}, λ_{i, 1}) | X | Off | Match (filtered) | No current |
| | (low-Q value) | | | | |
| X | Avg(λ_{i, 0}, λ_{i, 1}) | ρ | λ_{i, 0} and λ_{i, 1} | Match (filtered) | No current |
| | (low-Q value) | | | | |
| ρ | Detuned | 0 | λ_{i, 0} | Mismatch (passed) | Current |
| ρ | Detuned | 1 | λ_{i, 1} | Mismatch (passed) | Current |
| ρ | Detuned | X | Off | Match (filtered) | No current |
| ρ | Detuned | ρ | λ_{i, 0} and λ_{i, 1} | Mismatch (passed) | Current |

Table 9 includes the encoding scheme of Table 8 and adds the reject symbol “ρ.” To provide a data word symbol value dᵢ of logic ‘0’, logic ‘1’, or the wildcard value “X”, the input encoder 202 can be driven as described above in connection with Table 8. To provide a search word symbol value sᵢ of reject symbol “ρ”, comparison engine 401 can be detuned relative to the first wavelength (λ_{i,0}) and the second wavelength (λ_{i,1}). For example, resonant structure 418A can be tuned to represent a reject symbol ‘ρ’ by driving tuning component 427A to tune the resonance of the resonant structure 418A away from both of the first and second wavelengths (λ_{1,0} and λ_{1,1}). Thus, the light can pass through the comparison engine 401 when the data word symbol is set as logic ‘0’, logic ‘1’ or reject symbol “ρ”, as shown above in Table 9. Accordingly, the presence of light (e.g., light at or above the threshold amplitude A) can indicate that a data word symbol dᵢ of the data word 203 and the search word symbol sᵢ of the search word 414 at the respective symbol position are mismatched. As described above, the resonant structure 418A may operate as a band-stop filter, which in the case of a reject symbol “ρ”, may have a bandwidth that is narrow enough to pass both the first and second wavelengths (λ_{1,0} and λ_{1,1}). The bandwidth can be modified by tuning the Q-value of the resonant structures 418A, for example, by controlling the number of free carriers near or within the light-conducting medium 423A, as described above. Increasing the Q-value narrows the bandwidth. In some examples, the resonant structures 418A may be configured to minimize crosstalk and prevent blocking adjacent channels by tuning the −Q value, for example, increasing the Q-value reduces crosstalk.

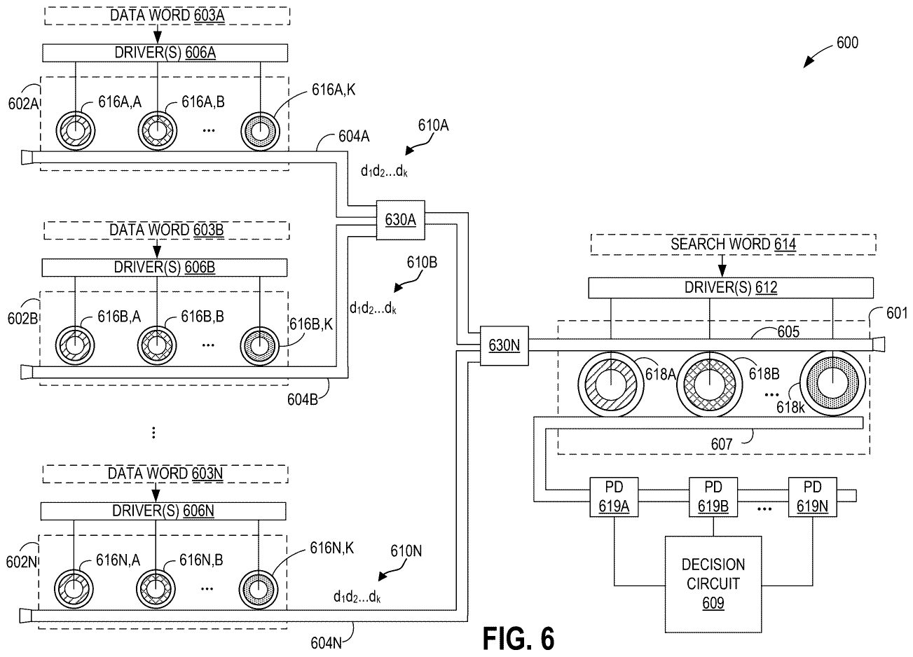

FIG. 6 is an optical search engine 600 in accordance another example of the present disclosure. In examples, the optical search engine 600 may be implemented to compare a plurality of data words 603A-603N (collectively referred to herein as data words 603 or singularly referred to herein as data word 603), each represented as symbols, to a search word 614 represented as symbols. The data words 603A-603N may be substantively similar to one or more of data words 103, 203, and/or 403. Likewise, the search word 614 may be substantively similar to one or more of search words described in connection with FIG. 1, search word 214, and/or search word 414. In various examples, optical search engine 600 performs the comparison optically using data words and search words that can be stored in a memory, such as data word storage 108 and search word storage 114 of FIG. 1, respectively. The optical search engine 600 is provided for illustrative purposes only and should not be interpreted as limiting the scope of the disclosed technology to only the depicted example.

In examples, the optical search engine 600 can include a plurality of input encoders 602A-602N (collectively referred to herein as input encoders 602 or singularly referred to herein as input encoder 602), associated with the data words 603 to enable comparison of the plurality of data words against the search word 614. The input encoders 602 may be implemented, for example, as input encoder 202 and/or input encoder 102. As such, data words 603 may be encoded by the input encoders according to one or more of the encoding schemes set forth in Tables 1, 4, and/or 9 to generate a plurality of encoded data word signals 610A-610N (collectively referred to herein as encoded data word signals 610 or singularly referred to herein as encoded data word signal 610) as described above in connection with FIGS. 1-4.

In the example of FIG. 6, each data word 603 may associated with a respective input encoder 602. For example, the symbols of a first data word 603A may be encoded by a first input encoder 602A to generate encoded data word signal 610A. For example, drivers(s) 606A (e.g., an example of drivers 206A-206K) can be used to drive resonant structures 616A,A through 616A, K (e.g., examples of resonant structures 216) to represent the symbol positions of the data word 603A. Likewise, the symbols of a second data word 603B may be encoded by a first input encoder 602B to generate encoded data word signal 610B (e.g., driver(s) 606B may drive resonant structures 616B,A through 616B,K), and so on to input encoder 602N that generates encoded data word signal 610N by encoding the symbols of an Nth data word 603N (e.g., driver(s) 606N may drive resonant structures 616N,A through 616N,K).

In examples, the input encoders 602 may be coupled to a plurality of input routing elements 604A-604N (collectively referred to herein as input routing elements 604 or singularly referred to herein as input routing element 604), which may be examples of input routing element 204A of FIGS. 2 and 4. The input routing elements 604 can be coupled to one or more coupling components 630A-630N to couple the encoded data word signals 610 from the input encoders 602 into the comparison engine 601. The one or more coupling components 630A-630N may be implemented as cascaded 2:1 optical combiners that optically couple light on two routing elements to a single routing element. Accordingly, each input routing element 604 can be configured to couple a corresponding encoded data word signal 610 with an adjacent encoded data word signal 610 from another input routing element 604 until an aggregate encoded data word signal 611 is provided to the comparison engine 601 via an input routing element 605 (e.g., an example of input routing element 204B as described in FIGS. 2 and 4). The cascaded 2:1 optical combiners are provided as an example. Other combiners may be utilized, such as a N:1 optical combiner.

To perform a plurality of search operations, the comparison engine 601 can be driven to store search word 614, in some examples. The comparison engine 601 may be implemented as comparison engine 201 of FIG. 2 and/or comparison engine 401 of FIG. 4. Accordingly, the comparison engine 601 can include one or more resonant structures 618A-618K (collectively referred to as resonant structures 618 or singularly as resonant structure 618) that can be modulated to store search word symbols of search word 614. The resonant structures 618A-618K may be examples of resonant structures 218 and/or 418 as described above and may be driven, via drivers 612A-612K (e.g., drivers 212A-212K and/or drivers 412A-412K) by an electronic signal to tune optical characteristics of the resonant structures 618A-618K. The symbols of search word 614 may be encoded onto optical signals according to the encoding schemes described in connection with Tables 2, 5, 7, and/or 9.

In examples, a resonant structure implemented as a waveguide resonator (e.g., an MRR) comprises a plurality of resonance wavelengths separated by the free spectral range (FSR) of the respective resonant structure. An initial resonance wavelength (λ₀) may be defined by a round-trip length of the waveguide resonator. In the case of MRRs, an initial resonate wavelength (λ₀) corresponds to a radius of the MRR defining the round-trip length. A given resonant structure may resonate at its respective initial resonance wavelength (λ₀) and respective resonance modes (e.g., λ₁, λ₂, λ₃, . . . , λₘ) separated by its respective FSR.

In examples, the comparison engine 601 can leverage the FSRs of resonant structures 618 to detect light on the input routing element 605 at a respective initial resonance wavelength (λ_{(0,i)}), as well as respective resonance modes (e.g., λ_{(1,i)}, λ_{(2,i)}, λ_{(3,i)}, . . . , λ_{(m,i)}). For example, driver(s) 612 (e.g., an example of drivers 212A-212K and/or drivers 412A-412K) can be configured to control tuning of resonant structures 618A-618K (e.g., examples of resonant structures 218 and/or resonant structures 418) so to resonate at initial resonance wavelengths, such that each resonant structure 618A-618K resonates at a distinct initial resonance wavelength (λ_{(0,i)}. As an illustrative example, resonant structure 618A may be driven to resonate at a first initial resonance wavelength (λ_{(0,1)}), resonant structure 618B may be driven to resonate at a second initial resonance wavelength (λ_{(0,2)}, and so on until resonant structure 618K, which can be driven to a Kth initial resonance wavelength (λ_{(0,K)}). Due to the FSRs, each resonant structure 618 may also resonate at respective resonance modes. For example, resonant structure 618A may also resonate at resonance mode wavelengths (λ_{(1,1)}, λ_{(2,1)}, λ_{(3,1)}, . . . , λ_{(m,1)}), resonant structure 618B may also resonate at resonance mode wavelengths (λ_{(1,2)}, λ_{(2,2)}, λ_{(3,2)}, . . . , λ_{(m,2)}), . . . , and resonant structure 618K may also resonate at resonance mode wavelengths (λ_{(1,K)}, λ_{(2,K)}, λ_{(3,K)}, . . . , λ_{(m,K)}). As a result, each resonant structure 618A-618K can couple light, from the input routing element 605, at its initial resonance wavelength and its respective resonance modes.

Leveraging the FSRs of the comparison engine 601, the input encoders 602 can be tuned to distinct wavelength ranges corresponding to the FSRs of the comparison engine 601. For example, a wavelength range for each input encoder 602 may be set to one FSR of the comparison engine 601, such that the resonant structures of a respective input encoder 602 can be tuned to resonance wavelengths within the set wavelength range. As an illustrative example, input encoder 602A may be set to a wavelength range encompassing initial resonances wavelengths of the comparison engine 601. In this case, resonant structures 616A,A-616A,K may be driven by driver(s) 606A to resonate and emit light at the initial resonance wavelengths of the resonant structures 618A-618K. That is, for example, resonant structure 616A,A may be driven to resonate and emit light at the first initial resonance wavelength (λ_{(0,1)}), resonant structure 616A,B may be driven to resonate and emit light at the second initial resonance wavelength (λ_{(0,2)}), and so on up to resonant structure 616A,K, which may be driven to resonate and emit light at the Kth initial resonance wavelength (λ_{(0,K)}).

Continuing with this example, input encoder 602B may be set to a wavelength range encompassing a second resonances mode of the comparison engine 601. In this case, resonant structures 616B,A-616B,K may be driven by driver(s) 606B to resonate and emit light at the second resonance mode of the resonant structures 618A-618K. That is, for example, resonant structure 616B,A may be driven to resonate and emit light at the first initial resonance wavelength (λ_{(1,1)}), resonant structure 616B,B may be driven to resonate and emit light at the second initial resonance wavelength (λ_{(1,2)}), and so on up to resonant structure 616B,K, which may be driven to resonate and emit light at the Kth initial resonance wavelength (λ_{(1,K)}. Likewise, input encoder 602N may be set to a wavelength range encompassing an mth resonances mode of the comparison engine 601. In this case, resonant structures 616N,A-616N,K may be driven by driver(s) 606N to resonate and emit light at the mth resonance mode of the resonant structures 618A-618K. That is, for example, resonant structure 616N,A may be driven to resonate and emit light at the first initial resonance wavelength (λ_{(m,1)}), resonant structure 616N,B may be driven to resonate and emit light at the second initial resonance wavelength (λ_{(m,2)}), and so on up to resonant structure 616N,K, which may be driven to resonate and emit light at the Kth initial resonance wavelength (λ_{(m,K)}).

Based on the logic states encoded into the comparison engine 601, light will couple into the resonant structures 618 for a respective encoded search symbol sᵢ when a mismatch occurs between the value of a symbol position of the data words 603 and the corresponding value of the symbol position of the search word 614. For example, light at the initial resonance wavelength and resonance modes will couple into a resonant structure 618 for a respective encoded search symbol sᵢ when a mismatch occurs between the value of a symbol position of the data words 603 and the corresponding value of the symbol position of the search word 614, according to the encoding schemes of Tables 3, 6, 8, and/or 9, depending on the implementation.

As an illustrative example, values of symbol position of the data word 603A can be encoded by the input encoder 602A using a wavelength range corresponding to the initial resonance wavelengths of the comparison engine according to any one of Tables 1, 4, and 9. To perform a search, values of the symbol positions of the search word 614 can be stored to the comparison engine 601 by tuning resonant structures 618A-618K to an initial resonance wavelength according to any one of Tables 2, 5, 7, and 9. Based on the logic states encoded into the comparison engine 601, light at initial resonance wavelengths will couple into a resonant structure 618 for a respective encoded search symbol sᵢ when a mismatch occurs between the value of a symbol position of the data word 603A and the corresponding value of the symbol position of the search word 614, according to the encoding schemes of Tables 3, 6, 8, and/or 9 (depending on the implementation). Similarly, values of symbol position of the data word 603B-603N can be encoded by the input encoders 602B-602N using respective resonance modes of the comparison engine. Light at respective resonance mode wavelengths will couple into a resonant structure 618 for a respective encoded search symbol sᵢ when a mismatch occurs between the value of a symbol position of the data words 603B-603N and the corresponding value of the symbol position of the search word 614, according to the encoding schemes of Tables 3, 6, 8, and/or 9 (depending on the implementation).

In the example of FIG. 6, the light coupled into the resonant structures 618A-618K may be routed to a plurality of photodetectors 619A-619N via an output routing element 607 (e.g., an example of output routing element 107). The resonant structures 618A-618K may be optically coupled (e.g., evanescently coupled) to the output routing element 607, such that any light coupled into the resonant structures 618A-618K from the input routing element 605 can be coupled onto the output routing element 607 and provided to the photodetectors 619A-619K. The photodetectors 619A-619N may comprise waveband filters configured to separate light on the output routing element 607 into wavebands corresponding to the FSRs of the comparison engine. For example, photodetector 619A may comprise a first waveband filter configured to separate light within a first FSR of the comparison engine 601, provide the filtered light to the photodetector that detects the intensity of light within the first FSR, and permits the rest of the light to pass to a downstream photodetector. In this case, the first FSR encompass the initial resonance wavelengths of the resonant structures 618A-618K. Photodetector 619B may comprise a second waveband filter configured to separate light within a second FSR of the comparison engine 601 (e.g., encompassing the first resonance modes of the resonant structures 618A-618K), which can be detected by the photodetector. Photodetector 619N may comprise an mth waveband filter configured to separate light within an mth FSR of the comparison engine 601 (e.g., encompassing the mth resonance modes of the resonant structures 618A-618K), which can be detected by the photodetector. In examples, the waveband filter may be implemented as waveband demultiplexers, such as, but not limited to, lattice filter demultiplexers, echelle gratings, and arrayed waveguide gratings, which can be constructed/sourced from readily available or modifications to silicon photonic foundry process design kits.

The photonic results, detected by the photodetectors 619A-619N, can be provided to a decision circuit 609 (e.g., an example of decision circuit 109, 209, and/or 409). For example, photodetectors 619A-619N detect intensities of light on the output routing element 607 and generate an electrical signals indicative of the light intensities therein. The electrical signal can be coupled to the decision circuit 609 that can receive a current from the photodetectors 619A-619N, determine a match/mismatch based on the current, and output a memory address corresponding to the data word represented by the encoded data word signals 610A-610N, according to the encoding schemes of Tables 3, 6, 8, and/or 9 (depending on the implementation).

FIGS. 7A and 7B depict a schematic diagram of an example optical device 700 in accordance with an example implementation of the present disclosure. FIG. 7A illustrates a top down view of the example optical device 700 and FIG. 7B illustrates a cross section view of the optical device 700 taken along the line I-I′ shown in FIG. 7A. The optical device 700 may be an example of a resonant structure 116 of FIG. 1, a resonant structure 716 of FIG. 7, and/or a resonant structure 616A,A through 616N,K of FIG. 6.

In the example, the optical device 700 comprises an optical device (also referred to as an optical memory device) as a resonator structure 702 optically coupled to a bus waveguide 704 (e.g., an example of input routing element 104, 704A, and/or 604A-604N). The resonator structure 702 may be an example of the light-conducting medium 213A-213K of FIG. 2. In some examples, port 706 may be coupled to the terminator 232 of FIG. 2 and port 718 of the bus waveguide 704 may be optically coupled to a comparison engine (e.g., comparison engine 101, 201, 401, and/or 601).

In the example of FIGS. 7A and 7B, the resonator structure 702 includes an optical waveguide 710 that can be optically coupled to the bus waveguide 704 via an optical coupler (not shown). The resonator structure 702 also comprises a mesa structure 714 formed on an integrated capacitive structure 712. The capacitive structure 712 (also sometimes referred to herein as a capacitor) may aid in the generation of light within the resonator structure 702, as well as the aiding in non-volatile tuning of the wavelength of this light. In some examples, the resonator structure 702 may comprise components formed of silica, silicon, or other Group IV material (e.g., germanium, silicon carbide, silicon germanium, and so on).

The resonator structure 702 may be a closed loop waveguide 710 formed of semiconductor material, such as silicon or other Group IV material. The shape of the loop may be, for example but not limited to, circular, elliptical, a racetrack shape, etc., thereby forming a ring resonator (e.g., a micro-ring resonator structure as shown in FIG. 7A). The resonator structure 702 may have a resonant frequency at which light propagates within the optical waveguide 710. The light propagating in the optical waveguide 710 can be evanescently coupled into (and/or out of) the bus waveguide 704 via the optical coupler according to a coupling coefficient.

The optical device 700, according to various implementations, can be configured for self-seeding (or self-injection locking) at a first wavelength of light generated by an optically active medium 754 of a mesa structure 714, as described below in connection with FIG. 7B. The mesa structure 714 may be an example of light emitting device 215A-215K of FIG. 2. For example, the mesa structure 714 may, in self-seeding implementations, be operated to cause an optically active medium 754 to generate light that can be injected into the optical waveguide 710 at the resonant frequency (e.g., first wavelength). As light resonating within the optical waveguide 710 may function as a seed signal that stimulates additional emissions at the wavelength of the seed signal (e.g., akin to an optical feedback). According to various illustrative implementations, the optically active medium 754 may include, but are not limited to, quantum dots (QD), quantum wells (QW), quantum-dash structures, or any structure that can create carrier population inversion for optical emissions in the waveguide. In these implementations, the light can be generated when a voltage bias (e.g., a seed voltage bias) is applied to the optically active medium 754 across the mesa structure 714, thereby stimulating emission (e.g., photoluminescence), for example in the case of quantum dots, by the optically active medium at a wavelength corresponding to the energy difference between conductance band and valence band or the transition between discretized energy states.

While the above examples are provided with reference to self-seeding approach, the optical device 700 may be configured for injection locking at the first wavelength, for example, generated by an external optical source received via ports 706 and coupled into the resonator structure 702 (e.g., in place of terminator 232). The received light may function as a seed signal for optical amplification, which causes the light emitting device to emit additional light at the frequency of the seed signal, thereby providing optical gain that amplifies the light propagating in the optical waveguide 710.

In examples, the capacitive structure 712 (which is hidden in view of FIG. 7A by the mesa structure 714) may be operated to provide non-volatile wavelength tuning, for example, as an example implementation of tuning components 217A-217K of FIG. 2, which can provide for non-volatile memory device for storing symbols of a data word. For example, the capacitive structure 712 may be configured to tune a wavelength of light generated by the mesa structure 714 from the first wavelength to a second wavelength by utilizing a non-volatile memory device, as described below in connection with FIG. 7B. For example, the capacitive structure 712 may include an insulating interface (e.g., dielectric layer 736) that comprises one or more defect sites (see FIG. 7B) that cause trap regions to develop that can trap or otherwise store carriers (e.g., electrons or holes) in the insulating interface. Applying a first voltage bias (e.g., a set voltage bias) across the capacitive structure 712 may cause an increase in the concentration of free charge carriers in the resonator structure 702 at a boundary of insulating interface due to carrier accumulation. This increased concentration can lead to increasing numbers of free charge carriers being trapped in the trap regions. The accumulation of trapped carriers within the insulating interface, which can remain stored in the insulating interface once the first voltage bias is removed, cause a non-volatile plasma dispersion effect that permanently (e.g., until the reset voltage bias is applied) alters the refractive index of the optical waveguide 710. The change in refractive index of the optical waveguide 710 induces a change in the resonance frequency of the resonator structure 702. The change in the resonance frequency likewise induces a change in the wavelength of light that can propagate within the resonator structure 702, thereby forcing a change in the wavelength of the light. As a result, the wavelength of the light coupled into the bus waveguide 704 can be tuned to the second wavelength.

Additionally, the application of a voltage bias across the capacitive structure 712 may be leveraged for tuning propagation loss in the optical waveguide 710. For example, applying a voltage can increase in the concentration of free charge carriers in the resonator structure 702 at a boundary of insulating interface through to carrier accumulation. Due to the overlap of the capacitive structure 712 with the optical waveguide 710, this increased concentration can lead to propagation loss, as well as the change in refractive index described above. By biasing the voltage applied between the electrodes 740 and 742, the propagation loss may be modulated accordingly, thereby inducing a change in the Q-value of the optical waveguide 710. Additional details on the propagation loss and refractive index change are provided, for example, in U.S. patent application Ser. No. 17/695,673, the disclosure of which is incorporated herein by reference.

As shown in FIG. 7B, in various examples, a buried oxide (BOX) layer 726 can be grown on a substrate 728, which may be provided as silicon. In an example, BOX layer 726 may comprise silicon dioxide (SiO₂). Other examples of materials for BOX layer 726 may include, but are not limited to, Silicon Nitride (Si₃N₄), Aluminum oxide (Al₂O₃), Hafnium Dioxide (HfO₂), diamond, silicon carbide (SiC), or combinations thereof. A first semiconductor layer 730 (referred to herein as a device layer 730) can be formed on the BOX layer 726.

The device layer 730 may comprise a first semiconductor material, such as but not limited to, silicon or other Group IV material (e.g., germanium, silicon carbide, silicon germanium, and so on). In some examples, the device layer 730 may be doped with a dopant of a first polarity. For example, the device layer may comprise positive dopants to provide a positively-doped semiconductor material (e.g., a p-type doped semiconductor layer). The device layer 730 may be formed by deposition, wafer bonding, monolithic growth, or other fabrication techniques. The device layer 730 may comprise a first portion 730a, a second portion 730b, and a third portion 730c. In some examples, the second portion 730b may be heavily doped such that the second portion 730b has a free charge carrier concentration that is higher than the first portion 730a.

Trenches 732 and 744 may be formed in the device layer 730 to separate portions 730b and 730c from portion 730a. Trenches 732 and 744 may be air gaps formed by etching or otherwise removing material from the device layer 730 according to known techniques. A narrow portion of material may remain in each trench 744 and 732 as shown in FIG. 7B; however, such configuration is optional and may be removed to expose the BOX layer 726.

A second semiconductor layer 734 may be formed on the device layer 730. The second semiconductor layer 734 may comprise a second semiconductor material that is dissimilar from the first material. For example, the second semiconductor layer 734 may comprise a Group III-V material, such as, but not limited to, InP, GaAS or other compounds of indium, gallium, phosphorus, and arsenic. In some examples, the second semiconductor layer 734 may be doped with a dopant of a second polarity. For example, the device layer may comprise negative dopants to provide a negatively-doped semiconductor material (e.g., an n-type doped semiconductor layer). The second semiconductor layer 734 may comprise a first portion 734a and a second portion 734b. In some examples, the second portion 734b may be heavily doped such that the second portion 734b has a free charge carrier concentration that is higher than the first portion 734a. The third portion 730c of device layer 730 may operate as a support structure formed between BOX layer 726 and the second portion 734b.

An insulating interface may be formed from a dielectric layer 736 between the device layer 730 and the second semiconductor layer 734. The dielectric layer 736 may be an electrically insulating material formed between the device layer 730 and the second semiconductor layer 734. The dielectric layer 736 can be native oxides of the cathode or the anode or both, or external dielectric materials such as high-k dielectrics or polymers that can be formed by deposition, oxidation, wafer bonding or other dielectric coating methods. In other examples, dielectric layer 736 may be formed from SiO₂, Si₃N₄, Al₂O₃, polyimides, transition metal oxides (e.g., HfO₂, titanium dioxide, zinc oxide, nickel oxide, etc.), organic materials, chalcogenides, 7D materials (e.g., molybdenum disulfide and the like), and ferroelectric materials, among others.

In examples, the dielectric layer 736 is formed at the boundary between the second semiconductor layer 734 and underlying portions of the device layer 730. A thin layer (e.g., on the order of tens of nanometers or less) of oxides of the second material (e.g., Group III-V oxides in an example) and oxides of the first material (e.g., silicon oxides in an example) may be provided between the second semiconductor layer 734 and underlying portions of the device layer 730, from which dielectric layer 736 forms naturally at this boundary and serves as a dielectric for the capacitive structure 712. In some examples, this thin layer has a thickness on a nanoscale, for example, a few nanometers thick. In some examples, steps need not be taken to encourage the formation of dielectric layer 736. In other examples, the formation of dielectric layer 736 may be stimulated, for example by elevating the temperature, exposing the materials to an oxygen-rich atmosphere, or other suitable technique.

Accordingly, the capacitive structure 712 can be defined between the first portion 730a of the device layer 730 and the first portion 734a of the second semiconductor layer 734 with the dielectric layer 736 acting as an insulator therebetween. In any case, the second portion 730b of the device layer 730 may be considered a first anode (e.g., where the device layer 730 is p-type doped) forming an electrical connection with the capacitive structure via the first portion 730a of the device layer 730, while the second portion 734b of the second semiconductor layer 734 may be considered a second portion 734b forming an electrical connection with the capacitive structure via the first portion 734a. In the case where the second material is a Group III-V material and the first material is silicon, the capacitive structure 712 may be a MOSCAP.

In the example shown in FIG. 7B, the dielectric layer 736 is formed continuously so as to overlap with the trench 732. In another example, the dielectric layer 736 may not be present within trench 732. In this case, two dielectric layers may be formed corresponding to the interface between the first portions 734a and 730a and the interface between the second portion 734b and the third portion 730c.

In the example of FIGS. 7A and 7B, the optical waveguide 710 is formed from the first portion 730a of the device layer and the first portion 734a of the second semiconductor layer 734, including the portion of dielectric layer 736 therebetween. Accordingly, the waveguide 710 includes the capacitive structure 712, such that second portion 730b electrically connects to the second portion 734b within the optical waveguide 710.

The dielectric layer 736 may include one or more defect sites as depicted in enlarged view 758 of portion 760 the optical waveguide 710, shown in FIG. 7B. The term “defect sites” as used herein may refer to imperfections in the bulk of the material of the insulating layer, surface imperfections at the boundaries of the insulating interface with other materials, or both. In some examples, the defect sites may be resulted from imperfections in the manufacturing process as well as intentionally created. The existence of the defect sites may cause the generation of trap regions 762 that can trap free charge carriers, such holes 764 and electrons 766. The refractive index of the optical waveguide 710 can depend on the amount of the free charge carriers at this interface, such that a change in the concentration of free charge carriers in the optical waveguide 710 can cause a change in the refractive index, as described below.

In examples, the first material may be a crystalline semiconductor material (e.g., crystalline silicon) and the second material maybe a crystalline semiconductor material (e.g., crystalline Group III-V material). The dielectric layer 736 may be an amorphous material (e.g., amorphous Al₂O₃). As a result, defect sites are formed due to the imperfect interface between the crystalline semiconductor material and amorphous semiconductor material that generate dangling bond carrier traps. These dangling bond carrier traps can serve to alter the carrier concentration within the waveguide 710 and induce non-volatile plasma dispersion-based wavelength shifts, as described herein.

In the example of FIGS. 7A and 7B, a contact electrode 740 may be disposed on the second portion 730b and a contact electrode 742 may be disposed on the second portion 734b. When a voltage bias is applied to electrodes 740 and 742, free charge carrier accumulation or depletion can occur at the boundaries of the dielectric layer 736. Due to the optical waveguide 710 overlapping with a region of capacitive structure 712, carrier concentration change may lead to changes in waveguide refractive index. As shown in the example of FIG. 7B, an entire cross-section of the optical waveguide 710, taken along line I-I′ shown in FIG. 7A, is included within the capacitive structure 712. By biasing the voltage applied between the electrodes 740 and 742, the refractive index may be altered accordingly, thereby shifting of wavelength carried by the optical waveguide 710.

The mesa structure 714 can be formed on the second semiconductor layer 734 on a side of the dielectric layer 736 opposite the optical waveguide 710. For example, the mesa structure 714 can be formed on the first portion 734a so to overlap with the optical waveguide 710 in the longitudinal direction. The mesa structure 714 may include a third semiconductor layer 750 formed on the first portion 734a of the second semiconductor layer 734. The third semiconductor layer 750 may comprise a third semiconductor material that is doped with a polarity opposite to the second semiconductor layer 734. For example, the third semiconductor layer 750 may be a positively-doped semiconductor material (e.g., a p-type doped semiconductor layer). The third material may comprise a Group III-V material, such as, but not limited to, InP, GaAS or other compounds of indium, gallium, phosphorus, and arsenic. The third material may be similar to the second material, except being oppositely doped.

The mesa structure 714 comprises an optically active medium 754 formed on the first portion 734a. The optically active medium 754 can be formed in the third semiconductor layer 750 adjacent to the second semiconductor layer 734. In some implementations, the optically active medium 754 may be grown in the third semiconductor layer 750, such that the layers are monolithic. The optically active medium 754 may comprise, for example, quantum dot (QD), quantum wells (QW), quantum-dash (QD) structures, or any structure that can create carrier population accumulation or depletion. In an example, the optically active medium 754 may comprise InAs and/or GaAs QDs.

An anode 752 (sometimes referred to as a second anode, e.g., where portion 730b is considered a first anode) may be formed in the third semiconductor layer 750 and an electrode 748 disposed thereon on a side of the optically active medium 754 opposite the dielectric layer 736. In some examples, the anode 752 may be a portion of the third semiconductor layer 750 that is heavily doped, for example, having the same doping polarity as third semiconductor layer 750 but a higher concentration of dopants than the rest of third semiconductor layer 750.

The mesa structure 714 can be formed to generate light, which can be coupled into the optical waveguide 710 by traversing the intervening layers. For example, a seed voltage bias can be applied across the mesa structure 714 via contact electrodes 742 and 748. Thus, the seed voltage bias is applied to optically active medium 754, which stimulates light emission at the resonant frequency. Due to the longitudinal overlap between mesa structure 714 and the optical waveguide 710, light generated by the mesa structure 714 can be coupled in the optical waveguide 710 by traversing the second semiconductor layer 734 and dielectric layer 736. The BOX layer 726, trench 732, and trench 744 may function to confine the light to the optical waveguide 710 in the lateral and longitudinal directions.

In an example, a forward voltage bias may be applied between the electrodes 748 and 742 (e.g., +V), for example, by the one or more power sources 708. The one or more power source 708 may be controlled by, for example, the programming controller 106 of FIG. 1, one or more of drivers 706A-206K of FIG. 7, and/or drivers 606A-606B of FIG. 6. The power sources 708 may act as a signal source and can include a negative terminal connected to the electrode 742 and a positive terminal connected the electrode 748. Applying the forward voltage bias can cause a carrier concentration change through accumulation that leads to stimulated emission in the optically active medium 754, thereby generating light. Emitted light traverses the layers and is injected into the optical waveguide 710 and resonators in the resonator structure 702. Accordingly, by biasing the voltage applied between the electrodes 742 and 752, a seed signal may be generated and provided to the optical waveguide 710 via mesa structure 714.

As alluded to above, a wavelength of light propagating in waveguide 710 (e.g., as generated by the mesa structure 714) can be altered due to refractive index changes induced by applying a first voltage bias to the capacitive structure 712. For example, power source(s) 708 may be connected to electrodes 742 and 740. Applying a reverse voltage bias (e.g., −V) results in a migration of negative charges from the second portion 734b toward the boundary the first portion 734a of the second semiconductor layer 734 adjacent to the dielectric layer 736 (e.g., within the optical waveguide 710). Additionally, positive charges (“holes”) migrate from the anode 730b to the boundary of the first portion 730a of the device layer 730 adjacent to the dielectric layer 736 (e.g., within the optical waveguide 710). This operation can be referred to as accumulation mode.

The migration of free charge carriers, e.g., holes and electrons, to the boundaries within the optical waveguide 710 can result in increased carrier concentrations at the interface with the dielectric layer 736. The increased concentrations can lead to an increasing number of free charge carriers being trapped in the trap regions 762 of the dielectric layer 736. The accumulation of trapped carriers, which remain trapped (e.g., stored) in the dielectric layer 736 even after the first voltage bias is removed, can cause a non-volatile plasma dispersion effect that permanently (e.g., until a reset voltage bias is applied) changes the refractive index of the optical waveguide 710. The change in refractive index induces a change in the resonance frequency of the resonator structure 702 that changes the wavelength of light propagating in the resonator structure 702.

The trapped carriers can be released by applying a forward voltage bias across electrodes 742 and 740. For example, the forward voltage bias may cause a migration of negative charges from the optical waveguide 710 toward second portion 734b operating as a cathode, and migration of holes from the optical waveguide 710 toward first portion 730a, operating as an anode (e.g., referred to as depletion mode). This migration of free charge carriers away from the boundaries within the optical waveguide 710 can result in decreased carrier concentrations at the interface with the dielectric layer 736. The decreased concentrations can lead to the release of free charge carriers from the trap regions 762, which changes the wavelength of light propagating in the resonator structure 702 back to the initial wavelength.

While certain materials are described as negatively- or positively-doped, implementations are not limited thereto, and the polarity doping may be switched. For example, while the above example described the second semiconductor layer 734 as negatively-doped and the device layer 730 as positively-doped, the polarity of each layer may be switched such that the second semiconductor layer 734 is positively-doped (e.g., providing an anode) and the device layer 730 may be negatively-doped. In this case, portion 734b may become an anode and portion 730b may become a cathode, and the polarity of the voltage bias may be reversed to achieve the above described functionality.

Additional details of the example optical device 700 are described, for example, in U.S. patent application Ser. No. 18/891,356, assigned to the Applicant and the disclosure of which is incorporated herein by reference.

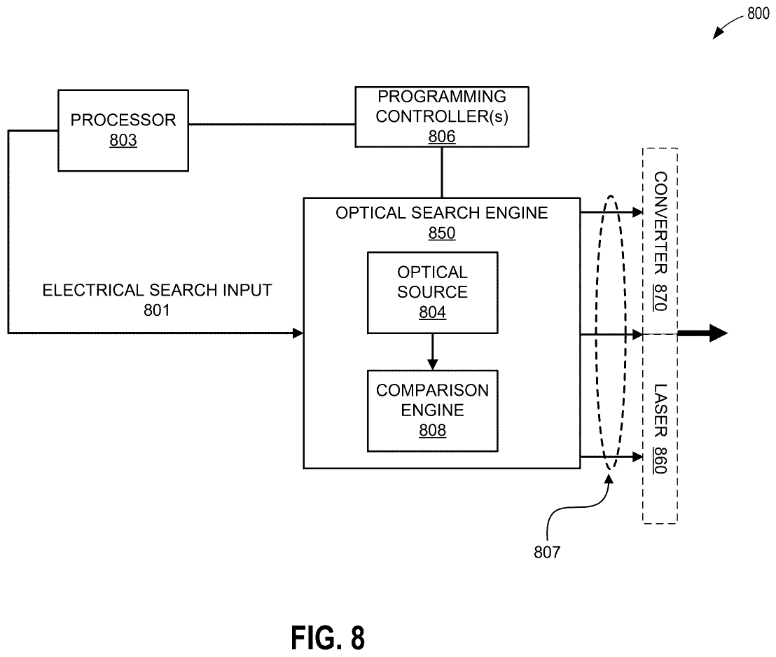

The optical search engines discussed with respect to FIGS. 1, 2, 4, and 6 can be implemented within a CAM component of a device, increasing the speed and efficiency of the search compared to traditional bCAMs. FIG. 8 illustrates an example computing device 800 in accordance with examples of the technology disclosed herein. The example computing device 800 is provided for illustrative purpose and should not be interpreted as limiting the scope of the technology only to the depicted example. The example computing device 800 may include more or fewer components in various examples. When common references are used between figures, it should be interpreted that all descriptions associated with such reference is applicable to all instances of the reference unless otherwise stated.

As shown in FIG. 8, the computing device 800 can comprise a processor 803. In various examples, the processor 803 can be one or more of a general purpose processor (GPU), an application specific integrated circuit (ASIC), a field programmable gate array (FPGA), or other computer processor device known in the art. In various examples, the processor 803 can comprise a co-processor configured to control operation of the QCAM search functionality of the computing device 800. In some examples, the processor 803 can be configured to send an electrical data word and/or an electrical search word to optical search engine 850. In various examples, the optical search engine 850 can be configured to implement the examples discussed above with respect to FIGS. 1, 2, 4, and 6. One or more applications executed by the processor 803 may request access to a portion of memory within the same network as the computing device 800 by submitting a data word and/or a search word electronically of the electrical search input line 801. The optical search engine 850 can encode the data word on the optical data word signals and store the search word, as discussed with respect to FIGS. 1, 2, 4, and 6. In various examples, the data word may be submitted to an optical source 804 of the optical search engine 850, which can optically submit the data word to a comparison engine 808.

In various examples, the optical source 804 may comprise one or more input encoders, as discussed with respect to FIGS. 1, 2, 4, and 6. The input encoder may be configured to generate an optical signal encoded with the data word. In some examples, the optical source 804 can comprise a plurality of optical sources configured to emit light at distinct wavelengths to represent the data word and an optical fiber or other optical transmission medium connected to one or more other components within the computing device 800 and/or to the interior output of a faceplate connector. The optical source 804 may receive the electrical data input 801 and encode the data word into optical data word signals as like that discussed with respect to FIGS. 1, 2, 4, and 6.

In various examples, the processor 803 can be communicatively coupled to one or more programming controllers 806. As discussed with respect to FIGS. 1, 2, 4, and 6, the programming controller 806 can be configured to program the plurality of resonant structures within the optical search engine 850 such that the state of each resonant structure is driven in accordance with the encoding scheme discussed with respect to Tables 1-9. In various examples, the processor 803 may send a data word to be stored and encoded to the programming controllers 806, which can then determine how the electrical drive signal should be encoded into the optical signals from the optical source 804. The programming controller 806 can be configured to program a plurality of resonant structures within the optical source 804 to represent the data word. In various examples, the processor 803 may also send a search word to be stored to the programming controllers 806, which can then determine how the electrical drive signal should be stored to the comparison engine 808. The programming controller 806 can be configured to program a plurality of resonant structures within the comparison engine 808 to represent the search word. In some examples, the processor 803 and the programming controllers 806 may be the same component. In some examples, the programming controllers 806 can be configured to receive instructions for operation of the resonant structures of the optical search engine 850 for each word.

After performing the search, one or more output signals 807 may be output by the optical search engine 850. In various examples, the output signals 807 can comprise one or more memory addresses in a memory component within the network and accessible by the computing device 800, whether directly or indirectly (i.e., through another device within the network), corresponding to one or more stored words represented by the plurality of resonant structures of the optical search engine 850 that were determined to match the search word. The output signal 807 can be sent to either a converter 870, a laser 860, or a combination of both. If the memory address corresponding to the matched data word(s) is to be sent to an electronic component (e.g., a memory controller directly connected to the computing device 800) to gain access to the content at the requested memory address(es), the output signal 807 can be sent to the converter 870, which is configured to convert the output signal into an electrical signal comprising the memory address(es). In various examples, the converter 870 may comprise an analog-to-digital converter (ADC). If the output signal 807 is to be sent optically to another entity (e.g., another computing device over an optical interconnect), the output signal 807 can be sent to a laser 860 configured to convert the output into an optical signal to be transmitted to another entity, such as a memory controller or another device.

The optical search engines discussed with respect to FIGS. FIGS. 1, 2, 4, and 6 can be implemented within an O-CAM component (e.g., an O-QCAM and/or O-TCAM) of a device (such as computing device 800) to execute various functions, increasing the speed and efficiency of the execution compared to traditional bCAMs with a reduced physical footprint.

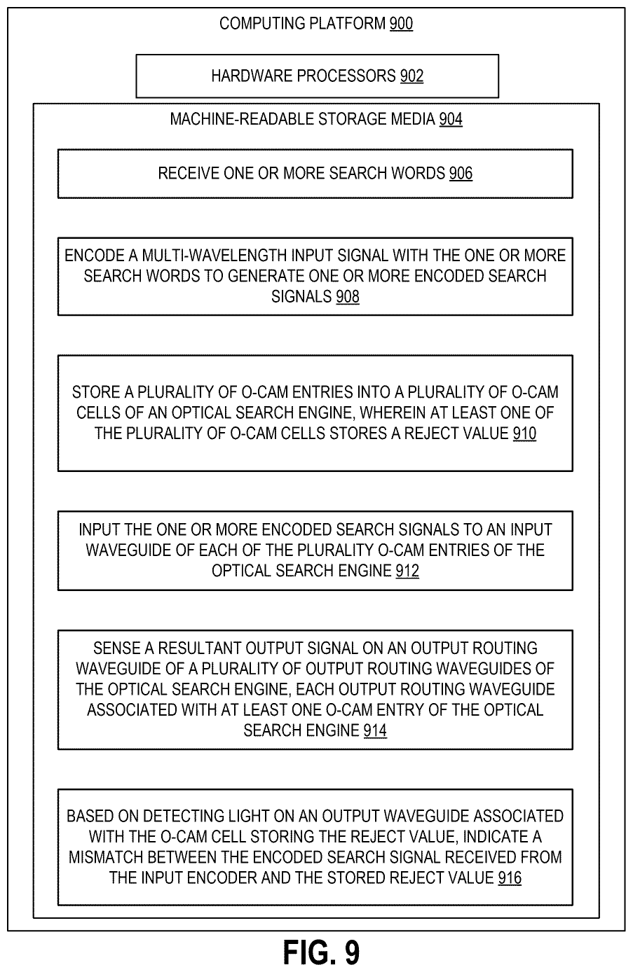

FIG. 9 illustrates a computing component that may be used to implement optical content addressable memory in accordance with various examples of the disclosed technology. Referring now to FIG. 9, computing component 900 may be, for example, a server computer, a controller, or any other similar computing component capable of processing data. In the example implementation of FIG. 9, the computing component 900 includes a hardware processor 902, and machine-readable storage medium for 904.

Hardware processor 902 may be one or more central processing units (CPUs), semiconductor-based microprocessors, and/or other hardware devices suitable for retrieval and execution of instructions stored in machine-readable storage medium 904. Hardware processor 902 may fetch, decode, and execute instructions, such as instructions 906-916, to control processes or operations disclosed herein. As an alternative or in addition to retrieving and executing instructions, hardware processor 902 may include one or more electronic circuits that include electronic components for performing the functionality of one or more instructions, such as a field programmable gate array (FPGA), application specific integrated circuit (ASIC), or other electronic circuits.

A machine-readable storage medium, such as machine-readable storage medium 904, may be any electronic, magnetic, optical, or other physical storage device that contains or stores executable instructions. Thus, machine-readable storage medium 904 may be, for example, Random Access Memory (RAM), non-volatile RAM (NVRAM), an Electrically Erasable Programmable Read-Only Memory (EEPROM), a storage device, an optical disc, and the like. In some examples, machine-readable storage medium 904 may be a non-transitory storage medium, where the term “non-transitory” does not encompass transitory propagating signals. As described in detail below, machine-readable storage medium 904 may be encoded with executable instructions, for example, instructions 906-916.

Hardware processor 902 may execute instruction 906 to receive, by an input encoder, a data word. In an example, the input encoder comprises a plurality of light emitting devices. Moreover, the input encoder may include a plurality of resonant structures comprising the plurality of light emitting devices and tuning components. In examples, the input encoder can be implemented as any one of input encoder 102, 202, and/or 602A-602N.

Hardware processor 902 may execute instruction 908 to encode, by the input encoder, a multi-wavelength input signal with the data word to generate an encoded data word signal. In some examples, encoding the multi-wavelength input signal comprises tuning the plurality of light emitting devices of the input encoder to emit light at a plurality of wavelengths to represent the data word.

In an example, the resonant structures of the input encoder (e.g., resonant structures 216 and/or 616A,A-616N,K) can be tuned according to an encoding scheme, such as those provided in Tables 1, 4, and/or 9, describe above. For example, the symbols, a resonant structure can be to tuned to emit light at a first wavelength to represent a logic ‘0’; emit light at a second wavelength to represent a logic ‘1’; tuned off to represent a wild card value; and emit light at the first and second wavelengths to represent a reject value.

Hardware processor 902 may execute instruction 910 to store, by a programming controller, a search word into a plurality of O-CAM cells of an optical comparison engine. In some examples, the plurality of O-CAM cells comprise a plurality of resonator structures. In this case, storing the search word into the plurality of O-CAM cells comprises tuning one or more resonance wavelengths of the plurality of resonant structure to represent symbols of the search word. In examples, the comparison engine can be implemented as any one of comparison engine 101, 201, 401, and/or 601.

In an example, the one or more resonance wavelengths of the plurality of resonant structure can be tuned according to an encoding scheme, such as those provided in Tables 3, 6, 8, and/or 9, describe above. For example, to represent the symbols of the search word, a resonant structure can be tuned to a second resonance wavelength of a respective O-CAM cell to represent a logic ‘0’; to a first resonance wavelength of the respective O-CAM cell to represent a logic ‘1’; detuned relative to the first and second resonance wavelengths to represent a wild card value; and to the first or second wavelength to represent a reject value. In another example, to represent the symbols of the search word, a resonant structure can be tuned to a first resonance wavelength of a respective O-CAM cell to represent a logic ‘0’; to a second resonance wavelength of the respective O-CAM cell to represent a logic ‘1’; to an average of the first and second resonance wavelengths to represent a wild card value; and to the first or second wavelength to represent a reject value.

Hardware processor 902 may execute instruction 912 to input, by the input encoder, the encoded data word signal to an input waveguide of the optical comparison engine. The input waveguide be optically coupled to the plurality of O-CAM cells. In examples, the input waveguide may be implemented as input routing element 104, 204A, 204B, input routing elements 604, and/or input routing element 605.

Hardware processor 902 may execute instruction 914 to sense, by one or more photodetectors, one or more resultant signals from the plurality of O-CAM cells. In examples, the photodetectors may be implemented as photodetectors 219, 419, and/or 619.

Hardware processor 902 may execute instruction 916 to, based on detecting light from the plurality of O-QCAM cells, indicate, by the one or more photodetectors, a mismatch between the encoded data word signal received from the input encoder and the stored search word. For example, the photodetectors may detect light, which can be indicative of a mismatch or match according to the encoding scheme (e.g., encoding scheme set forth in Tables 3, 6, 8, and/or 9). The photodetectors generate a current that can be provided to a decision circuit (e.g., decision circuit 109, 209, 409, and/or 609) which can determine a match/mismatch based on the current, and output a memory address corresponding to the data word represented by the encoded data word signals, according to the encoding schemes.

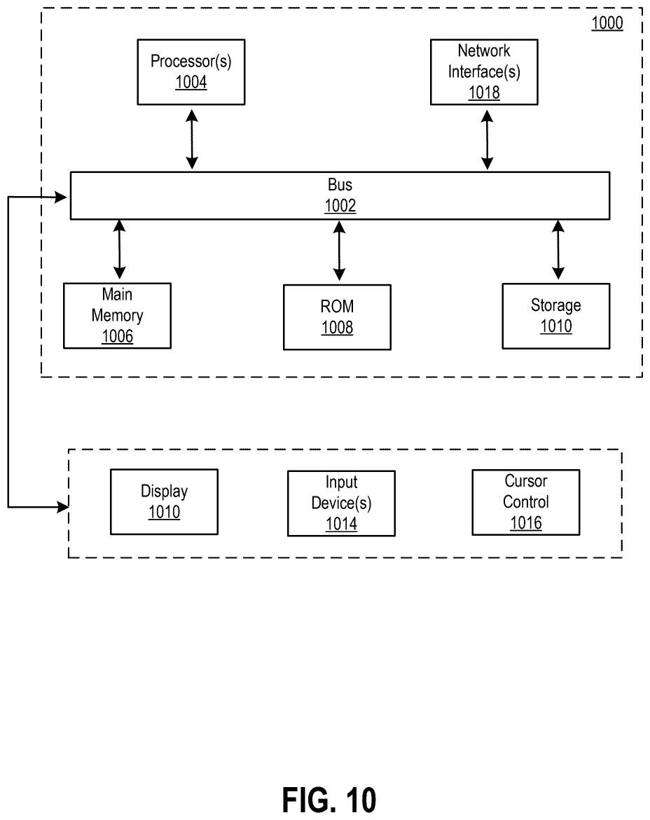

FIG. 10 depicts a block diagram of an example computer system 1000 in which various examples of the disclosed technology described herein may be implemented. The computer system 1000 includes a bus 1002 or other communication mechanism for communicating information, one or more hardware processors 1004 coupled with bus 1002 for processing information. Hardware processor(s) 1004 may be, for example, one or more general purpose microprocessors. The computer system 1000 may be implemented as one or more component of the optical search engines described in connection with FIGS. 1, 2, 4, 6, and 8, for example, programming controller, driver(s), data word storage, search word storage, etc.

The computer system 1000 also includes a main memory 1006, such as a random access memory (RAM), cache and/or other dynamic storage devices, coupled to bus 1002 for storing information and instructions to be executed by processor 1004. Main memory 1006 also may be used for storing temporary variables or other intermediate information during execution of instructions to be executed by processor 1004. Such instructions, when stored in storage media accessible to processor 1004, render computer system 1000 into a special-purpose machine that is customized to perform the operations specified in the instructions. For example, main memory 1006 may store instructions, that when executed by processor(s) 1004, cause computer system 1000 to perform one or more of the operations described in connection with FIG. 9.

The computer system 1000 further includes a read only memory (ROM) 1008 or other static storage device coupled to bus 1002 for storing static information and instructions for processor 1004. A storage device 1010, such as a magnetic disk, optical disk, or USB thumb drive (Flash drive), etc., is provided and coupled to bus 1002 for storing information and instructions.

The computer system 1000 may be coupled via bus 1002 to a display 1012, such as a liquid crystal display (LCD) (or touch screen), for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. In some examples, the same direction information and command selections as cursor control may be implemented via receiving touches on a touch screen without a cursor.

The computing system 1000 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 1000 may implement the techniques described herein using customized hard-wired logic, one or more ASICs or FPGAs, firmware and/or program logic which in combination with the computer system causes or programs computer system 1000 to be a special-purpose machine. According to one example of the disclosed technology, the techniques herein are performed by computer system 1000 in response to processor(s) 1004 executing one or more sequences of one or more instructions contained in main memory 1006. Such instructions may be read into main memory 1006 from another storage medium, such as storage device 1010. Execution of the sequences of instructions contained in main memory 1006 causes processor(s) 1004 to perform the process steps described herein. In alternative examples, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 1010. Volatile media includes dynamic memory, such as main memory 1006. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 1002. Transmission media can also take the form of acoustic or light waves, such as those generated during radio-wave and infra-red data communications.

The computer system 1000 also includes a network interface 1018 (also referred to as a communication interface) coupled to bus 1002. Network interface 1018 provides a two-way data communication coupling to one or more network links that are connected to one or more local networks. For example, communication interface 1018 may be an integrated services digital network (ISDN) card, cable modem, satellite modem, or a modem to provide a data communication connection to a corresponding type of telephone line. As another example, network interface 1018 may be a local area network (LAN) card to provide a data communication connection to a compatible LAN (or WAN component to communicated with a WAN). Wireless links may also be implemented. In any such implementation, network interface 1018 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical signals that carry digital data streams. The signals through the various networks and the signals on network link and through network interface 1018, which carry the digital data to and from computer system 1000, are example forms of transmission media.

The computer system 1000 can send messages and receive data, including program code, through the network(s), network link and network interface 1018. In the Internet example, a server might transmit a requested code for an application program through the Internet, the ISP, the local network and the network interface 1018.

The received code may be executed by processor 1004 as it is received, and/or stored in storage device 1010, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed examples. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAS, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 1000.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain examples include, while other examples do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. An optical content-addressable memory (O-CAM) comprising:
an input encoder comprising a plurality of light emitting devices configured to store a data word and generate a plurality of optical signals encoded with the data word as a multi-wavelength input signal;
a comparison engine comprising a plurality of O-CAM cells, the O-CAM cells comprising resonant structures configured to store a search word; and
one or more photodetectors optically coupled to the comparison engine,
wherein a respective O-CAM cell is configured to store one of:
a logic ‘0’;
a logic ‘1’;
a wildcard value; and
a reject value.

2. The O-CAM of claim 1, wherein the one or more photodetectors are configured to detect a mismatch between the data word and the search word by detecting light of at least one wavelength of the multi-wavelength input signal.

3. The O-CAM of claim 1, wherein the one or more photodetectors comprise a plurality of photodetectors that are optically coupled to the plurality of O-CAM cells, wherein respective photodetectors are optically coupled to corresponding O-CAM cells, and wherein the respective photodetectors are configured to detect a mismatch between the data word and the search word by detecting light from the respective O-CAM cells.

4. The O-CAM of claim 3, wherein the resonant structures comprise microring modulators, each respective microring modulator is tunable to be resonate at one or more of a first wavelength or a second wavelength of the multi-wavelength input signal, wherein the respective microring modulator is configured to store:
the logic ‘0’ by tuning the respective microring modulator to the second wavelength;
the logic ‘1’ by tuning the respective microring modulator to the first wavelength;
the wildcard value by detuning the respective microring modulator relative to the first and second wavelengths; and
the reject value by tuning the respective microring modulator to the first and second wavelengths.

5. The O-CAM of claim 1, wherein the O-CAM cells are optically coupled to a waveguide optically coupled to the one or more photodetectors at an output end, wherein the one or more photodetectors are configured to detect a mismatch between the data word and the search word by detecting light from the output end of the waveguide.

6. The O-CAM of claim 5, wherein the resonant structures comprise microring modulators, each respective microring modulator is tunable to be resonate at one or more of a plurality of wavelengths, wherein the respective microring modulator is configured to store:
the logic ‘0’ by tuning the respective microring modulator to a first wavelength;
the logic ‘1’ by tuning the respective microring modulator to a second wavelength;
the wildcard value by tuning the respective microring modulator to block the first and second wavelengths; and
the reject value by detuning the respective microring modulator relative to the first and second wavelengths.

7. The O-CAM of claim 1, wherein a respective light emitting device is configured to store one of:
a logic ‘0’;
a logic ‘1’;
a wildcard value; and
a reject value.

8. The O-CAM of claim 1, wherein the plurality of light emitting devices comprises a plurality of microring lasers, each respective microring laser is tunable to emit light at a first wavelength or a second wavelength of the multi-wavelength input signal, wherein the respective microring laser is configured to store:
the logic ‘0’ by tuning the respective microring laser to the first wavelength;
the logic ‘1’ by tuning the respective microring laser to the second wavelength;
the wildcard value by deactivating the respective microring laser; and
the reject value by tuning the respective microring laser to the first and second wavelengths simultaneously.

9. A method, comprising:
receiving, by an input encoder, a data word;
encoding, by the input encoder, a multi-wavelength input signal with the data word to generate an encoded data word signal;
storing, by a programming controller, a search word into a plurality of optical content addressable memory (O-CAM) cells of an optical comparison engine;
inputting, by the input encoder, the encoded data word signal to an input waveguide of the optical comparison engine, wherein the input waveguide is optically coupled to the plurality of O-CAM cells;
sensing, by one or more photodetectors, one or more resultant signals from the plurality of O-CAM cells; and
based on detecting light from the plurality of O-QCAM cells, indicating, by the one or more photodetectors, a mismatch between the encoded data word signal received from the input encoder and the stored search word.

10. The method of claim 9, further comprising:
receiving, by the programming controller, the search word to be stored in the plurality of O-CAM cells, the search word comprising a plurality of search word symbols; and
storing, by the programming controller, a symbol value for each search word symbol of the plurality of search word symbols within a O-CAM cell of the plurality of O-CAM cells.

11. The method of claim 9, further comprising:
receiving, by the programming controller, a data word to be encoded into the encoded data word signal, the data word comprising a plurality of data word symbols; and
storing, by the programming controller, a data word symbol value for each data word symbol of the plurality of data word symbols within a resonant structure of the input encoder,
wherein the input encoder comprises a plurality of resonant structures configured to emit light at a plurality of wavelengths based on the data word symbol values.

12. The method of claim 9, wherein the plurality of O-CAM cells comprise a plurality of resonator structures, and wherein storing the search word into the plurality of O-CAM cells comprises tuning one or more resonance wavelengths of the plurality of resonant structure to represent symbols of the search word.

13. The method of claim 12, wherein tuning one or more resonance wavelengths of the plurality of resonant structure to represent the symbols of the search word comprises:
tuning a resonant structure to a second resonance wavelength of a respective O-CAM cell to represent a logic ‘0’;
tuning the resonant structure to a first resonance wavelength of the respective O-CAM cell to represent a logic ‘1’;
detuning the resonant structure relative to the first and second resonance wavelengths to represent a wild card value; and
tuning the resonant structure to the first and second wavelength to represent a reject value.

14. The method of claim 12, wherein tuning one or more resonance wavelengths of the plurality of resonant structures to represent the symbols of the search word comprises:
tuning a resonant structure to a first resonance wavelength of a respective O-CAM cell to represent a logic ‘0’;
tuning the resonant structure to a second resonance wavelength of the respective O-CAM cell to represent a logic ‘1’;
tuning the resonant structure to block the first and second resonance wavelengths to represent a wild card value; and
detuning the resonant structure relative to the first and second wavelength to represent a reject value.

15. The method of claim 9, wherein the input encoder comprises a plurality of light emitting devices, and wherein encoding the multi-wavelength input signal with the data word to generate the encoded data word signal comprises tuning the plurality of light emitting devices to emit light at a plurality of wavelengths to represent the data word.

16. The method of claim 15, wherein tuning the plurality of light emitting device to emit light at the plurality of wavelengths to represent the data word comprises:
tuning a light emitting device to emit light at a first wavelength to represent a logic ‘0’;
tuning the light emitting device to emit light at a second wavelength to represent a logic ‘1’;
tuning off the light emitting device to represent a wild card value; and
tuning the light emitting device to emit light at the first and second wavelengths to represent a reject value.

17. An optical content addressable memory (O-CAM), comprising:
one or more input encoders configured to emit one or more multi-wavelength input signals representative of one or more data words;
an optical comparison engine optically coupled to the one or more input encoders, the optical comparison engine comprising a plurality of O-CAM cells configured to store a search word; and
one or more photodetectors optically coupled to the plurality of O-CAM cells of the optical comparison engine,
wherein the optical comparison engine is configured to couple light of the one or more multi-wavelength input signals to the one or more photodetectors to indicate a mismatch between a symbol of the search word and a symbol of the data word.

18. The O-CAM of claim 17, wherein the one or more input encoders comprise one or more memory bank laser circuits.

19. The O-CAM of claim 18, wherein the one or more memory bank laser circuits comprise a plurality of resonant structures, the plurality of resonant structures comprise a plurality of light emitting devices configured to store symbols of the one or more data words.

20. The O-CAM of claim 17, wherein the optical comparison engine comprises a cascaded microring modulator circuit that includes a plurality of resonator structures configured to store the search word.
